(19) United States
(12) Patent Application Publication
(10) Pub. No.: US 2024/0119582 A1
(43) Pub. Date: Apr. 11, 2024

(54) A MACHINE LEARNING MODEL USING TARGET PATTERN AND REFERENCE LAYER PATTERN TO DETERMINE OPTICAL PROXIMITY CORRECTION FOR MASK

(71) Applicant: ASML NETHERLANDS B.V., Veldhoven (NL)

(72) Inventors: Quan ZHANG, San Jose, CA (US); Been-Der CHEN, Milpitas, CA (US); Wei-chun Fong, Sunnyvale, CA (US); Zhangnan ZHU, San Jose, CA (US); Robert Elliott BOONE, San Jose, CA (US)

(21) Appl. No.: 18/276,018

(22) PCT Filed: Jan. 31, 2022
(86) PCT No.: PCT/EP2022/052213

§ 371 Date: Aug. 4, 2023

Related U.S. Application Data
(60) Provisional application No. 63/152,693, filed on Feb. 23, 2021.

(51) Int. Cl. G06T 7/00; G03F 1/36

(52) U.S. Cl. CPC G06T 7/001; G03F 1/36; G06T 2207/20081; G06T 2207/20212; G06T 2207/30148

(57) ABSTRACT

Described are embodiments for generating a post-optical proximity correction (OPC) result for a mask using a target pattern and reference layer patterns. Images of the target pattern and reference layers are provided as an input to a machine learning (ML) model to generate a post-OPC image. The images may be input separately or combined into a composite image (e.g., using a linear function) and input to the ML model. The images are rendered from pattern data. For example, a target pattern image is rendered from a target pattern to be printed on a substrate, and a reference layer image such as dummy pattern image is rendered from dummy pattern. The ML model is trained to generate the post-OPC image using multiple images associated with target patterns and reference layers, and using a reference post-OPC image of the target pattern. The post-OPC image may be used to generate a post-OPC mask.

### CROSS-REFERENCE TO RELATED APPLICATIONS

This application claims priority of U.S. application 63/152,693 which was filed on 23 Feb. 2021, and which is incorporated herein in its entirety by reference.

### TECHNICAL FIELD

The description herein relates to lithographic apparatuses and processes, and more particularly to determining corrections for a patterning mask.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g., comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a wafer stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally<1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, microlithography is a central step in the manufacturing of ICs, where patterns formed on substrates define functional elements of the ICs, such as microprocessors, memory chips etc. Similar lithographic techniques are also used in the formation of flat panel displays, micro-electromechanical systems (MEMS) and other devices.

As semiconductor manufacturing processes continue to advance, the dimensions of

functional elements have continually been reduced while the amount of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k 1 lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC) in the design layout, or other methods generally defined as “resolution enhancement techniques” (RET).

### SUMMARY

In some embodiments, there is provided a non-transitory computer-readable medium having instructions that, when executed by a computer, cause the computer to execute a method for 35 training a machine learning model using a composite image of a target pattern and reference layer patterns to predict a post-optical proximity correction (OPC) image, wherein the post-OPC image is used to obtain a post-OPC mask for printing a target pattern on a substrate. The method includes: obtaining (a) target pattern data representative of a target pattern to be printed on a substrate and (b) reference layer data representative of a reference layer pattern associated with the target pattern; rendering a target image from the target pattern data and a reference layer pattern image from the reference layer pattern; generating a composite image by combining the target image and the reference layer pattern image; and training a machine learning model with the composite image to predict a post-OPC image until a difference between the predicted post-OPC image and a reference post-OPC image corresponding to the composite image is minimized

In some embodiments, there is provided a non-transitory computer readable medium having instructions that, when executed by a computer, cause the computer to execute a method for generating a post-optical proximity correction (OPC) image, wherein the post-OPC image is used in generating a post-OPC mask pattern to print a target pattern on a substrate. The method includes: providing an input that is representative of images of (a) a target pattern to be printed on a substrate and (b) a reference layer pattern associated with the target pattern to a machine learning model; and generating, using the machine learning model, a post-OPC result based on the images.

In some embodiments, there is provided a non-transitory computer readable medium having instructions that, when executed by a computer, cause the computer to execute a method for generating a post-optical proximity correction (OPC) image, wherein the post-OPC image is used to generate a post-OPC mask to print a target pattern on a substrate. The method includes: providing a first image representing a target pattern to be printed on a substrate and a second image representing a reference layer pattern associated with the target pattern to a machine learning model; and generating, using the machine learning model, a post-OPC image based on the target pattern and the reference layer pattern.

In some embodiments, there is provided a non-transitory computer readable medium having instructions that, when executed by a computer, cause the computer to execute a method for generating a post-optical proximity correction (OPC) image, wherein the post-OPC image is used to generate a post-OPC mask to print a target pattern on a substrate. The method includes: providing a composite image representing (a) a target pattern to be printed on a substrate and (b) a reference layer pattern associated with the target pattern to a machine learning model; and generating, using the machine learning model, a post-OPC image based on the target pattern and the reference layer pattern.

In some embodiments, there is provided a non-transitory computer readable medium having instructions that, when executed by a computer, cause the computer to execute a method for training a machine learning model to generate a post-optical proximity correction (OPC) image. The method includes: obtaining input related to (a) a first target pattern to be printed on a first substrate, (b) a first reference layer pattern associated with the first target pattern, and (c) a first reference post-OPC image corresponding to the first target pattern; and training the machine learning model using the first target pattern and the first reference layer pattern such that a difference between the first reference post-OPC image and a predicted post-OPC image of the machine learning model is reduced.

In some embodiments, there is provided a method for generating a post-optical proximity correction (OPC) image, wherein the post-OPC image is used in generating a post-OPC mask pattern to print a target pattern on a substrate. The method includes: providing an input that is representative of images of (a) a target pattern to be printed on a substrate and (b) a reference layer pattern associated with the target pattern to a machine learning model; and generating, using the machine learning model, a post-OPC result based on the images.

In some embodiments, there is provided a method for generating a post-optical proximity correction (OPC) image, wherein the post-OPC image is used to generate a post-OPC mask to print a target pattern on a substrate. The method includes: providing a first image representing a target pattern to be printed on a substrate and a second image representing a reference layer pattern associated with the target pattern to a machine learning model; and generating, using the machine learning model, a post-OPC image based on the target pattern and the reference layer pattern.

In some embodiments, there is provided a method for generating a post-optical proximity correction (OPC) image, wherein the post-OPC image is used to generate a post-OPC mask to print a target pattern on a substrate. The method includes: providing a composite image representing (a) a target pattern to be printed on a substrate and (b) a reference layer pattern associated with the target pattern to a machine learning model; and generating, using the machine learning model, a post-OPC image based on the target pattern and the reference layer pattern.

In some embodiments, there is provided a method for training a machine learning model to generate a post-optical proximity correction (OPC) image. The method includes: obtaining input related to (a) a first target pattern to be printed on a first substrate, (b) a first reference layer pattern associated with the first target pattern, and (c) a first reference post-OPC image corresponding to the first target pattern; and training the machine learning model using the first target pattern and the first reference layer pattern such that a difference between the first reference post-OPC image and a predicted post-OPC image of the machine learning model is reduced.

In some embodiments, there is provided an apparatus for generating a post-optical proximity correction (OPC) image, wherein the post-OPC image is used in generating a post-OPC mask pattern to print a target pattern on a substrate. The apparatus includes: a memory storing a set of instructions; and a processor configured to execute the set of instructions to cause the apparatus to perform a method, which includes: providing an input that is representative of images of (a) a target pattern to be printed on a substrate and (b) a reference layer pattern associated with the target pattern to a machine learning model; and generating, using the machine learning model, a post-OPC result based on the images.

### BRIEF DESCRIPTION OF THE DRAWINGS

FIG. 1 shows a block diagram of various subsystems of a lithography system.

FIG. 2 shows a flow for a patterning simulation method, according to an embodiment.

FIG. 3 shows a flow for a measurement simulation method, according to an embodiment.

FIG. 4 is a block diagram of a system for predicting a post-OPC image for a mask, in accordance with one or more embodiments.

FIG. 5 is a block diagram of a system for generating pattern images from pattern data, in accordance with one or more embodiments.

FIG. 6A is a block diagram of a system for generating a composite image from multiple pattern images, in accordance with one or more embodiments.

FIG. 6B is a block diagram of the system illustrating generation of an example composite image from target pattern and context layer pattern images, in accordance with one or more embodiments.

FIG. 7 is a system for training a post-OPC image generator machine learning model configured to predict a post-OPC image for a mask, in accordance with one or more embodiments.

FIG. 8 is a flow chart of a method of training the post-OPC image generator configured to predict a post-OPC image for a mask, in accordance with one or more embodiments.

FIG. 9 is a flow chart of a method for determining a post-OPC image for a mask, in accordance with one or more embodiments.

FIG. 10 is a flow diagram illustrating aspects of an example methodology of joint optimization, according to an embodiment.

FIG. 11 shows an embodiment of another optimization method, according to an embodiment.

FIGS. 12A, 12B and 13 show example flowcharts of various optimization processes, according to an embodiment.

FIG. 14 is a block diagram of an example computer system, according to an embodiment.

FIG. 15 is a schematic diagram of a lithographic projection apparatus, according to an embodiment.

FIG. 16 is a schematic diagram of another lithographic projection apparatus, according to an embodiment.

FIG. 17 is a more detailed view of the apparatus in FIG. 16, according to an embodiment.

FIG. 18 is a more detailed view of the source collector module SO of the apparatus of FIGS. 16 and 17, according to an embodiment.

FIG. 19 shows a method of reconstructing a level-set function of a contour of a curvilinear mask pattern, in accordance with one or more embodiments.

### DETAILED DESCRIPTION

In lithography, a patterning device (e.g., a mask) may provide a mask pattern (e.g., mask design layout) corresponding to a target pattern (e.g., target design layout), and this mask pattern may be transferred onto a substrate by transmitting light through the mask pattern. However, due to various limitations, the transferred pattern may appear with many irregularities and therefore, not be similar to the target pattern. Various enhancement techniques, such as optical proximity correction (OPC), are used in designing the mask pattern to compensate for image errors due to diffraction or other process effects in lithography. Machine learning (ML) models can be used to predict post-OPC patterns (e.g., a pattern that is subjected to OPC process) for a given target pattern and corrections may be made, e.g., to mask pattern based on the predicted patterns to obtain the desired pattern on the substrate.

According to the present disclosure, reference layer patterns are incorporated in OPC machine leaning prediction of a main or target layer. This advantageously introduces the patterning effect from the one or more reference layers of a layout to the OPC correction of a target layer, thereby enabling context-aware OPC prediction by the ML model. The reference layers may be neighboring layers of the target layer. Particularly, a reference layer is a design layer or a derived layer different from the target pattern layer that may impact the manufacturing process of the target pattern layer and therefore impact the correction of the target pattern layer in the OPC process. For example, a reference layer pattern may be a context layer pattern or a dummy pattern. A context layer pattern may be a pattern, such as a contact pattern under or above the target pattern, that provides context for the target pattern, for example, the electrical connectivity between the context layer and the target pattern. The context layer patterns may have an overlap with the target patterns and may not be visible. The dummy patterns may include patterns that are not in the target pattern, but their presence may make the production steps more stable. The dummy patterns are typically placed away from the target patterns and the sub-resolution assist features (SRAF), to have a more uniform density of patterns. The dummy patterns may be treated less significantly (e.g., than the SRAF patterns or sub-resolution inverse features (SRIF) layer patterns).

Further, in the present disclosure, images are generated based on target patterns, SRAF patterns, SRIF patterns, and reference layer patterns and used as training data to train a ML model, or used as input data to a trained ML model to predict a post-OPC pattern. For example, a target pattern image may be generated by obtaining target pattern and rendering the target pattern image from the target pattern. An SRAF image may be generated by obtaining SRAF pattern and rendering the SRAF pattern image from the SRAF pattern. An SRIF image may be generated by obtaining SRIF pattern and rendering the SRIF pattern image from the SRIF pattern. Similarly, reference layer patterns images may be generated by obtaining reference layer patterns such as context or dummy patterns, and rendering an image from each of the reference layer patterns. The images may be input either individually to the ML model (e.g., as separate by concurrent channels of input), or combined to a single composite image prior to being input to the ML model for training or prediction. By using a composite image that is generated by combining the rendered pattern images as training data, rather than a pattern image that is rendered from combined pattern data generated by performing a Boolean operation on the different patterns, consumption of computing resources in generating the training data may be significantly minimized, and accuracy of the OPC process is improved by considering the reference layers.

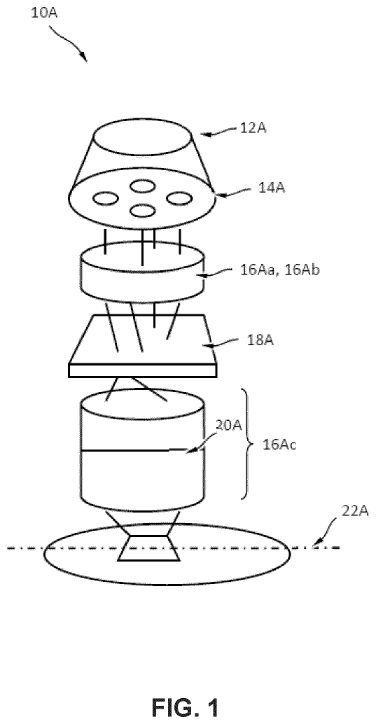

FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e., radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array. An example of such a construction is given in U.S. Pat No. 5,229,872, which is incorporated herein by reference.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

Variables of a patterning process are called “processing variables.” The patterning process may include processes upstream and downstream to the actual transfer of the pattern in a lithography apparatus. A first category may be variables of the lithography apparatus or any other apparatuses used in the lithography process. Examples of this category include variables of the illumination, projection system, substrate stage, etc. of a lithography apparatus. A second category may be variables of one or more procedures performed in the patterning process. Examples of this category include focus control or focus measurement, dose control or dose measurement, bandwidth, exposure duration, development temperature, chemical composition used in development, etc. A third category may be variables of the design layout and its implementation in, or using, a patterning device. Examples of this category may include shapes and/or locations of assist features, adjustments applied by a resolution enhancement technique (RET), CD of mask features, etc. A fourth category may be variables of the substrate. Examples include characteristics of structures under a resist layer, chemical composition and/or physical dimension of the resist layer, etc. A fifth category may be characteristics of temporal variation of one or more variables of the patterning process. Examples of this category include a characteristic of high frequency stage movement (e.g., frequency, amplitude, etc.), high frequency laser bandwidth change (e.g., frequency, amplitude, etc.) and/or high frequency laser wavelength change. These high frequency changes or movements are those above the response time of mechanisms to adjust the underlying variables (e.g., stage position, laser intensity). A sixth category may be characteristics of processes upstream of, or downstream to, pattern transfer in a lithographic apparatus, such as spin coating, post-exposure bake (PEB), development, etching, deposition, doping and/or packaging.

As will be appreciated, many, if not all of these variables, will have an effect on a parameter of the patterning process and often a parameter of interest. Non-limiting examples of parameters of the patterning process may include critical dimension (CD), critical dimension uniformity (CDU), focus, overlay, edge position or placement, sidewall angle, pattern shift, etc. Often, these parameters express an error from a nominal value (e.g., a design value, an average value, etc.). The parameter values may be the values of a characteristic of individual patterns or a statistic (e.g., average, variance, etc.) of the characteristic of a group of patterns.

The values of some or all of the processing variables, or a parameter related thereto, may be determined by a suitable method. For example, the values may be determined from data obtained with various metrology tools (e.g., a substrate metrology tool). The values may be obtained from various sensors or systems of an apparatus in the patterning process (e.g., a sensor, such as a leveling sensor or alignment sensor, of a lithography apparatus, a control system (e.g., a substrate or patterning device table control system) of a lithography apparatus, a sensor in a track tool, etc.). The values may be from an operator of the patterning process.

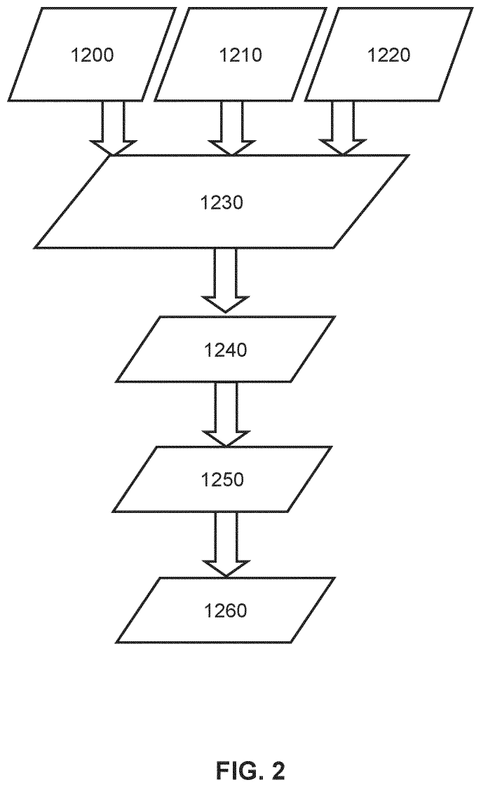

An exemplary flow chart for modelling and/or simulating parts of a patterning process is illustrated in FIG. 2. As will be appreciated, the models may represent a different patterning process and need not comprise all the models described below. A source model 1200 represents optical characteristics (including radiation intensity distribution, bandwidth and/or phase distribution) of the illumination of a patterning device. The source model 1200 can represent the optical characteristics of the illumination that include, but not limited to, numerical aperture settings, illumination sigma (G) settings as well as any particular illumination shape (e.g., off-axis radiation shape such as annular, quadrupole, dipole, etc.), where G (or sigma) is outer radial extent of the illuminator.

A projection optics model 1210 represents optical characteristics (including changes to the radiation intensity distribution and/or the phase distribution caused by the projection optics) of the projection optics. The projection optics model 1210 can represent the optical characteristics of the projection optics, including aberration, distortion, one or more refractive indexes, one or more physical sizes, one or more physical dimensions, etc.

The patterning device/design layout model module 1220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 1220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 1230 can be simulated from the source model 1200, the projection optics model 1210 and the patterning device/design layout model 1220. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 1250 can be simulated from the aerial image 1230 using a resist model 1240. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 1210.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 1260. The post-pattern transfer process model 1260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

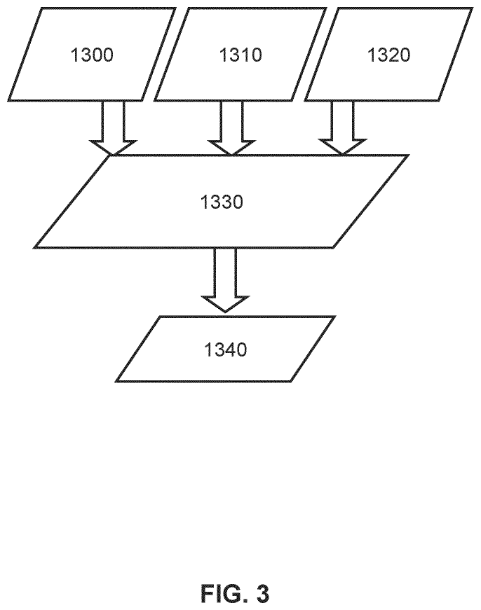

An exemplary flow chart for modelling and/or simulating a metrology process is illustrated in FIG. 3. As will be appreciated, the following models may represent a different metrology process and need not comprise all the models described below (e.g., some may be combined). A source model 1300 represents optical characteristics (including radiation intensity distribution, radiation wavelength, polarization, etc.) of the illumination of a metrology target. The source model 1300 can represent the optical characteristics of the illumination that include, but not limited to, wavelength, polarization, illumination sigma (G) settings (where G (or sigma) is a radial extent of illumination in the illuminator), any particular illumination shape (e.g., off-axis radiation shape such as annular, quadrupole, dipole, etc.), etc.

A metrology optics model 1310 represents optical characteristics (including changes to the radiation intensity distribution and/or the phase distribution caused by the metrology optics) of the metrology optics. The metrology optics 1310 can represent the optical characteristics of the illumination of the metrology target by metrology optics and the optical characteristics of the transfer of the redirected radiation from the metrology target toward the metrology apparatus detector. The metrology optics model can represent various characteristics involving the illumination of the target and the transfer of the redirected radiation from the metrology target toward the detector, including aberration, distortion, one or more refractive indexes, one or more physical sizes, one or more physical dimensions, etc.

A metrology target model 1320 can represent the optical characteristics of the illumination being redirected by the metrology target (including changes to the illumination radiation intensity distribution and/or phase distribution caused by the metrology target). Thus, the metrology target model 1320 can model the conversion of illumination radiation into redirected radiation by the metrology target. Thus, the metrology target model can simulate the resulting illumination distribution of redirected radiation from the metrology target. The metrology target model can represent various characteristics involving the illumination of the target and the creation of the redirected radiation from the metrology, including one or more refractive indexes, one or more physical sizes of the metrology, the physical layout of the metrology target, etc. Since the metrology target used can be changed, it is desirable to separate the optical properties of the metrology target from the optical properties of the rest of the metrology apparatus including at least the illumination and projection optics and the detector. The objective of the simulation is often to accurately predict, for example, intensity, phase, etc., which can then be used to derive a parameter of interest of the patterning process, such overlay, CD, focus, etc.

A pupil or aerial image 1330 can be simulated from the source model 1300, the metrology optics model 1310 and the metrology target model 1320. A pupil or aerial image 1330 is the radiation intensity distribution at the detector level. Optical properties of the metrology optics and metrology target (e.g., properties of the illumination, the metrology target and the metrology optics) dictate the pupil or aerial image.

A detector of the metrology apparatus is exposed to the pupil or aerial image and detects one or more optical properties (e.g., intensity, phase, etc.) of the pupil or aerial image. A detection model module 1340 represents how the radiation from the metrology optics is detected by the detector of the metrology apparatus. The detection model can describe how the detector detects the pupil or aerial image and can include signal to noise, sensitivity to incident radiation on the detector, etc. So, in general, the connection between the metrology optics model and the detector model is a simulated pupil or aerial image, which arises from the illumination of the metrology target by the optics, redirection of the radiation by the target and transfer of the redirected radiation to the detectors. The radiation distribution (pupil or aerial image) is turned into detection signal by absorption of incident energy on the detector.

Simulation of the metrology process can, for example, predict spatial intensity signals, spatial phase signals, etc. at the detector or other calculated values from the detection system, such as an overlay, CD, etc. value based on the detection by the detector of the pupil or aerial image. Thus, the objective of the simulation is to accurately predict, for example, detector signals or derived values such overlay, CD, corresponding to the metrology target. These values can be compared against an intended design value to, e.g., correct the patterning process, identify where a defect is predicted to occur, etc.

Thus, the model formulation describes most, if not all, of the known physics and chemistry of the overall metrology process, and each of the model parameters desirably corresponds to a distinct physical and/or chemical effect in the metrology process.

In the present disclosure, methods and systems are disclosed for generation of images based on a target pattern, SRAF pattern, SRIF pattern and reference layer patterns, and using them as input to predict a post-OPC pattern. The images may be input either individually to the ML model, or combined to a single composite image prior to being input to the ML model for training. After the ML model is trained, the trained ML model may be used to predict a post-OPC pattern for any given images of target pattern, SRAF pattern, SRIF pattern and reference layer patterns.

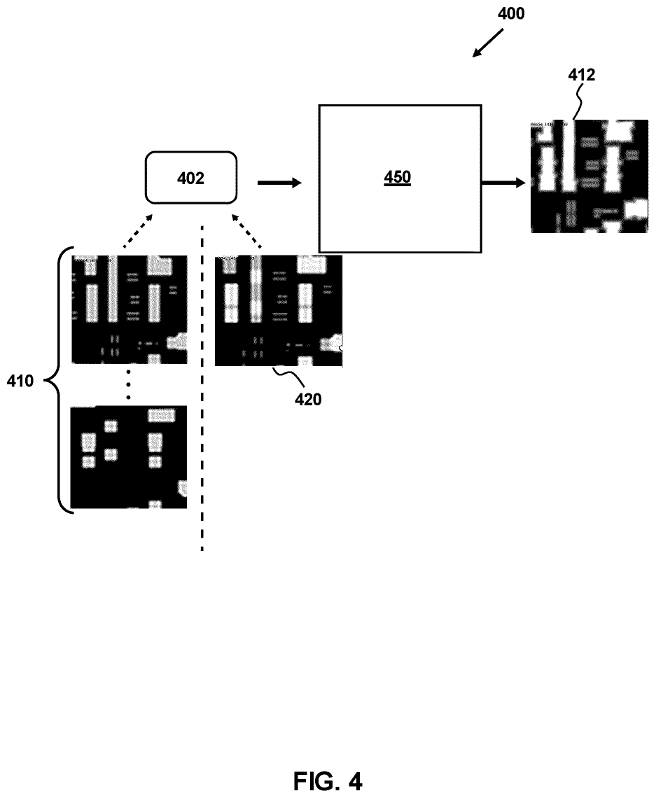

FIG. 4 is a block diagram of a system 400 for generating a post-OPC image for a mask, in accordance with one or more embodiments. The system 400 includes a post-OPC image generator 450 that is configured to generate a post-OPC image 412 of a mask pattern based on an input 402 that is representative of (a) a target pattern to be printed on a substrate, (b) SRAF or SRIF pattern associated with the target pattern, and (c) reference layer patterns that are associated with the target pattern (e.g., which are context patterns to be considered in OPC process to ensure coverage of, or electric connectivity to, these context patterns). In some embodiments, the post-OPC image 412 may be prediction of a rendered image of a mask pattern corresponding to the target pattern. In some embodiments, the predicted post-OPC image 412 may be prediction of a reconstructed image of the mask pattern. In some embodiments, the mask pattern might be modified or preprocessed before reconstructed into image, for example smoothing out corners. In some embodiments, a reconstructed image is an image that is typically reconstructed from an initial image of the mask pattern to match a given pattern, using a level-set method, that is, the reconstructed image defines a mask very close to input mask pattern when taking a threshold at certain constant value. In some embodiments, the image reconstruction may involves solving the inverse of level-set method directly or by an iterative solver/optimization. The post-OPC image 412 may be used as the mask pattern in the mask and this mask pattern may be transferred onto a substrate by transmitting light through the mask.

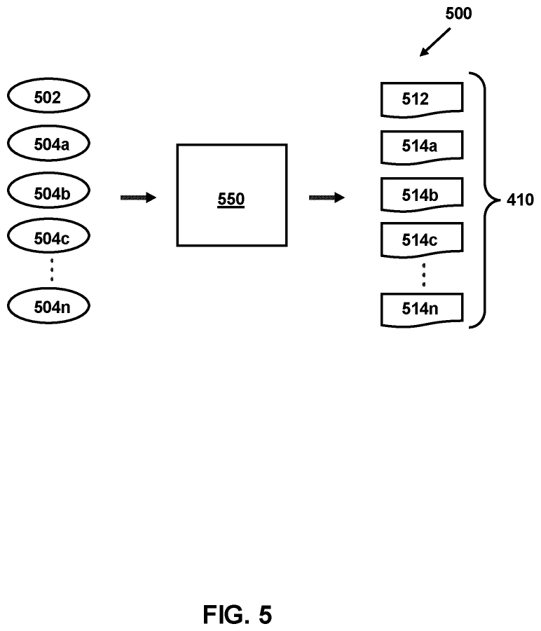

The input 402 may be provided to the post-OPC image generator 450 in various formats. For example, the input 402 may include a collection of images 410 having an image of the target pattern, SRAF pattern image or SRIF pattern image and images of reference layers patterns (e.g., context layer pattern image, dummy pattern image). That is, if there is one image of the target pattern, one SRAF pattern image and two images of reference layer patterns, four images may be provided as input 402 to the post-OPC image generator 450. Details of generating or rendering images 410 of the patterns are described at least with reference to FIG. 5 below. The SRAFs or SRIFs may include features which are separated from the target features but assist in their printing, while not being printed themselves on the substrate.

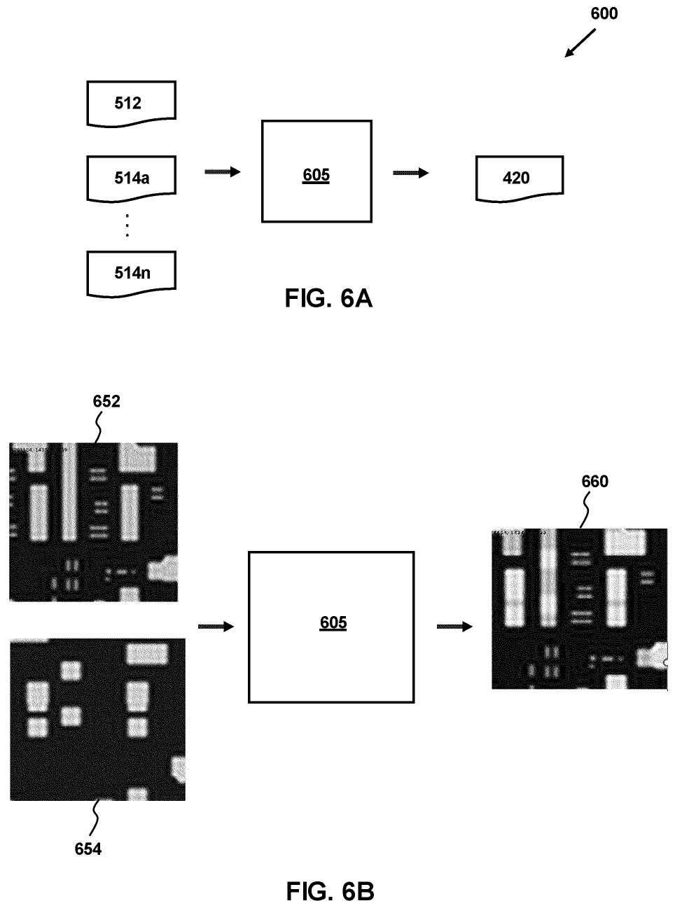

In another example, the input 402 may be a composite image 420 that is a combination of the target pattern image and the reference layer pattern images and this single composite image 420 may be input to the post-OPC image generator 450. Details of generating the composite image 420 are described at least with reference to FIG. 6A below.

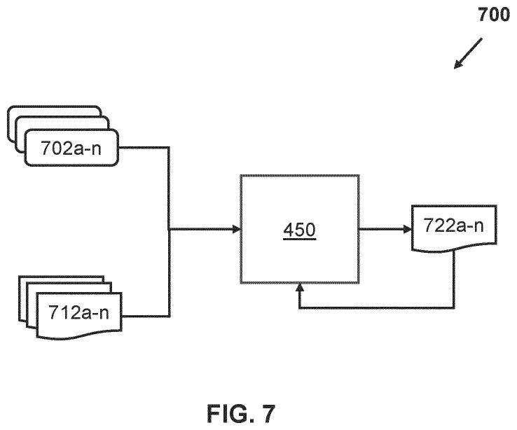

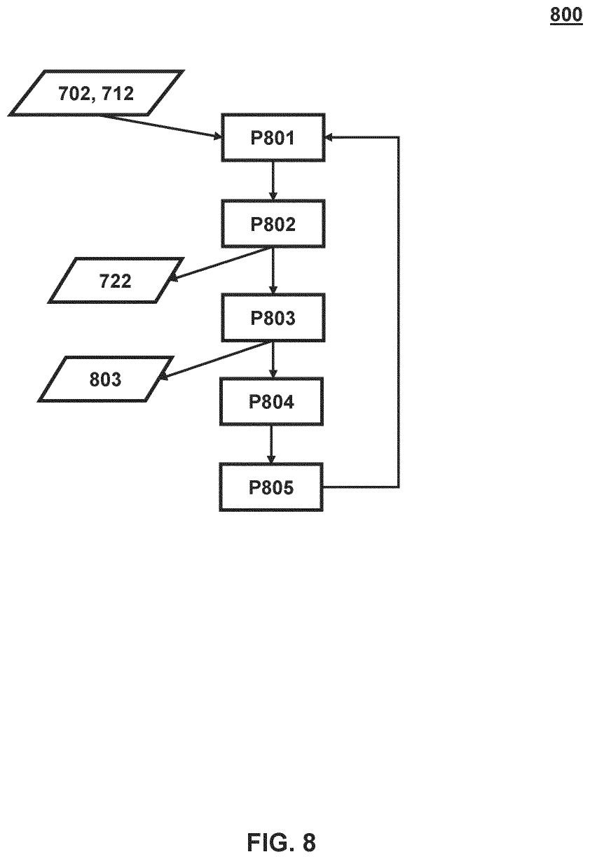

In some embodiments, the post-OPC image generator 450 may be a machine learning model (e.g., a deep convolutional neural network (CNN)) that is trained to predict a post-OPC image of a mask pattern. The present disclosure is not limited to any specific type of neural network of the machine learning model. The post-OPC image generator 450 may be trained using a number of images of each pattern (e.g., such as images 512 and 514a-n) as training data, or using a number of composite images. In some embodiments, the post-OPC image generator 450 is trained using the composite image as it may be less complex, and less time consuming to build or train a machine learning model with a single input than multiple inputs. A type of input provided to the post-OPC image generator 450 during a prediction process may be similar to the type of input provided during the training process. For example, if the post-OPC image generator 450 is trained with a composite image as the input 402, then for the prediction, the input 402 is a composite image as well. Additional details with respect to the training process is described below at least with reference to FIGS. 7 and 8 below.

FIG. 5 is a block diagram of a system 500 for rendering pattern images from pattern data, in accordance with one or more embodiments. The system 500 includes an image renderer 550 that renders a pattern image from pattern data, or pre-OPC patterns. For example, the image renderer 550 renders a target pattern image 512 from target pattern data 502. The target pattern data 502 (also referred to as “pre-OPC design layout”) includes target features or main features to be printed on the substrate. Similarly, the image renderer 550 renders pattern images for SRAFs, SRIFs based on pattern data associated with the SRAF or SRIF, and renders pattern images for each of the reference layers, such as context layer, dummy pattern or other reference layers, based on pattern data associated with those reference layers (also referred to as “reference layer pattern data”). For example, the image renderer 550 generates an SRAF pattern image 514a based on the SRAF pattern data 504a, context layer pattern image 514b based on the context layer pattern data 504b, dummy pattern image 514c based on the dummy pattern data 504c, and so on.

In some embodiments, each of the images 512 and 514a-n is a pixelated image comprising a plurality of pixels, each pixel having a pixel value representative of a feature of a pattern. The image renderer 550 may sample each of the features or shapes in the pattern data to generate an image. In some embodiments, rendering an image from pattern data involves obtaining geometric shapes (e.g., polygon shapes such as square, rectangle, or circular shapes, etc.) of the design layout, and generating, via image processing, a pattern image from the geometric shapes of the design layout. In some embodiments, the image processing comprises a rasterization operation based on the geometric shapes. For example, the rasterization operation that converts the geometric shapes (e.g. in vector graphics format) to a pixelated image. In some embodiments, the rasterization may further involve applying a low-pass filter to clearly identify feature shapes and reduce noise.

Additional details with reference to rendering an image from pattern data are described in PCT Patent Publication No. WO2020169303, which is incorporated by reference in its entirety.

In some embodiments, the target pattern data 502 and the reference layer pattern data 504 may be obtained from a storage system, which stores the pattern data in a digital file format (e.g., GDSII or other formats).

FIG. 6A is a block diagram of a system 600 for generating a composite image from multiple pattern images, in accordance with one or more embodiments. The system 600 includes an image mixer 605 that combines multiple images into a single image. For example, the target pattern image 512, SRAF pattern image 514a, and the reference layer pattern images such as context layer pattern image 514b, dummy pattern image 514c and other images may be provided as input to the image mixer 605, which combines them into a single composite image 420. The composite image 420 may include the information or data of all the images combined.

The image mixer 605 may combine the images 512 and 514a-514n in various ways to generate the composite image 420. In some embodiments, the composite image 420 may be represented as a function of the individual images, which may be expressed as:

I_{composite}=f(Iₘₐᵢₙ, I_{sraf}, I_{srif}, I_{context}, I_{dummy}, Iₒₜₕₑᵣₛ) (1)

where I_{composite} represents the composite image 420, Iₘₐᵢₙ represents the target pattern image 512, I_{sraf} represents the SRAF pattern image 514a, I_{srif} represents the SRIF pattern image, I_{context} represents the context layer pattern image 514b, I_{dummy} represents the dummy pattern image 514c and Iₒₜₕₑᵣₛ represents other reference layer pattern images. The function can be in any suitable form without departing from the scope of the present disclosure.

As an example, the images may be combined using a linear function, which may be expressed as:

I_{composite}=CₘₐᵢₙIₘₐᵢₙ+C_{sraf}I_{sraf}+C_{srif}I_{srif}+C_{context}I_{context}C_{dummy}I_{dummy}+CₒₜₕₑᵣₛIₒₜₕₑᵣₛ (2)

where Cₘₐᵢₙ, C_{sraf} and C_{srif} may be linear coefficients (e.g., may have values 1, 1, −1, respectively, or other values), C_{context}, C_{dummy} and Cₒₜₕₑᵣₛ may be linear combination coefficients of the respective pattern image.

FIG. 6B is a block diagram of the system 600 illustrating generation of an example composite image from target pattern and context layer pattern images, in accordance with one or more embodiments. A first image 652 and a context layer pattern image 654 are provided as input to the image mixer 605, which combines them into a single composite image 660. The composite image 660 may include the information or data of both the images combined. For example, in the composite image 660, portions of the context layer pattern image 654 are superimposed on portions of the first image 652. In some embodiments, the first image 652 may be similar to the target pattern image 512 or may be a combination of the target pattern image 512, SRAF pattern image 514a or one or more reference layer pattern images such as the dummy pattern image 514c. The context layer pattern image 654 may be similar to the context layer pattern image 514b, and not encompassed in the first image 652. In some embodiments, the composite image 660 is similar to the composite image 420.

The following description illustrates training of the post-OPC image generator 450 with reference to FIGS. 7 and 8. FIG. 7 is a system 700 for training a post-OPC image generator 450 machine learning model to predict a post-OPC image for a mask, in accordance with one or more embodiments. FIG. 8 is a flow chart of a process 800 of training the post-OPC image generator 450 to predict a post-OPC image for a mask, in accordance with one or more embodiments. The training is based on images associated with a pre-OPC layout (e.g., design layout of a target pattern to be printed on a substrate), SRAF patterns, SRIF patterns and reference layer patterns, such as context layer pattern, dummy pattern or other reference layer patterns. In some embodiments, the pre-OPC data and reference layer pattern data may be input as separate data (e.g., as different images, such as collection of images 410) or as combined data (e.g., a single composite image, such as composite image 420). The model is trained to predict a post-OPC image that closely matches a reference image (e.g., a reconstructed image). The following training method is described with reference to the input data being a composite image, but the input data could also be separate images.

In an operation P801, a composite image 702a that is a combination of a target pattern image, any SRAF pattern image or SRIF pattern image, and reference layer pattern images is obtained. In some embodiments, the composite image 702a may be generated by combining an image of a target pattern to be printed on the substrate with any images of SRAF pattern or SRIF pattern and images of reference layer patterns (e.g., context layer pattern image, dummy pattern image or other reference layer pattern images) as described at least with reference to FIG. 6A.

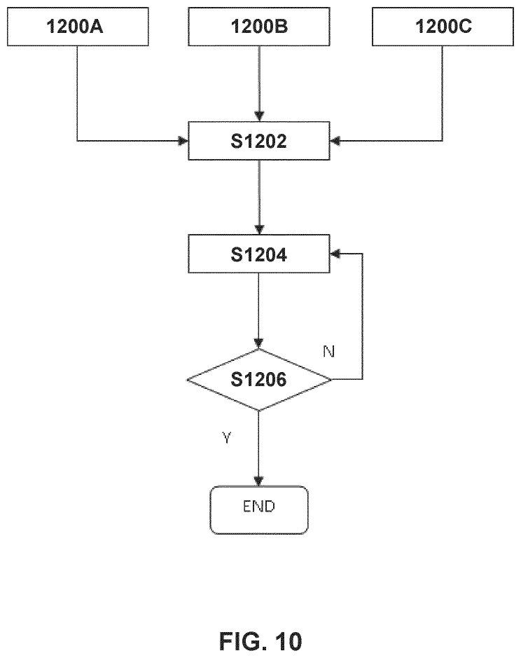

Further, a reference post-OPC image 712a corresponding to the composite image 702a is obtained, e.g., used as ground truth post-OPC image for the training. In some embodiments, the reference post-OPC image 712a may be an image of a post-OPC mask pattern corresponding to the target pattern. In some embodiments, the obtaining of the reference post-OPC image 712a involves performing a mask optimization process on a starting mask resulting from an OPC process or a source mask optimization process using the target pattern. Example OPC processes are further discussed with respect to FIGS. 10-13.

In some embodiments, the reference post-OPC image may be a rendered image of post-OPC mask pattern corresponding to the target pattern, as described in PCT Patent Publication No. WO02020169303, which is incorporated by reference in its entirety. Rendering an image of the post-OPC mask pattern may use the same rendering technique as rendering an image of a pre-OPC pattern, as described above in greater detail. However, the present disclosure is not limited thereto. In some embodiments, the reference post-OPC image 712a may be obtained from a ML model that is trained to generate an image of a post-OPC mask pattern.

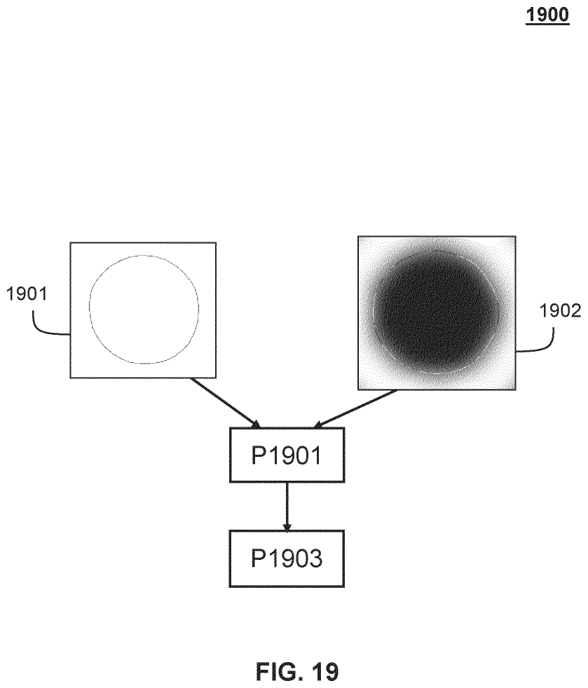

In some other embodiments, the reference post-OPC image 712a may be a reconstructed image of the mask pattern. In some embodiments, a reconstructed image is an image that is typically reconstructed from an initial image of a mask pattern to match the mask pattern, using a level-set method. Additional details of the generating the reconstructed image of the mask pattern are described at least with reference to FIG. 19 below.

The following paragraphs describe generating a reconstructed image by reconstructing a level-set function of a contour of a curvilinear mask pattern. In some embodiments, to find a level-set function ∅(x, y) for the curvilinear mask pattern, such that the level-set ∅(x, y)=C defines a set of contours or polygons, which, when interpreted as the mask patterns of the features at boundaries, producing a wafer pattern with little distortions and artifacts compared to the target patterns. The wafer pattern results from a photolithography process using the mask pattern obtained herein. The extent to which the set of contours defined by a level-set function ∅(x, y) is optimal is calculated based on a performance metric such as a differential of an edge placement error between a predicted wafer pattern and a target pattern is reduced.

Given a curvilinear mask polygon p (or a contour), we want to reconstruct, for example, an image ∅ which is approximately the level set function/image of the polygon p, which means the polygon corresponding to image ∅ is very close to original polygon, p′≈p. Here C is the threshold of contour tracing.

p′{(x₁, x₂, . . . , x_{N})|∅(x₁, x₂, . . . , x_{N})≡C}

FIG. 19 shows a method 1900 of reconstructing a level-set function of a contour of a curvilinear mask pattern, in accordance with one or more embodiments. In other words, an inverse mapping (loosely speaking) from the contour to generate an input level-set image. The method 1900 can be used to generate an image to initialize the CTM+ optimization in a region nearby the patch boundary.

The method, in process P1901, involves obtaining (i) the curvilinear mask pattern 1901 and a threshold value C, (ii) an initial image 1902, for example the mask image rendered from the curvilinear mask pattern 1901. In an embodiment, the mask image 1902 is a pixelated image comprising a plurality of pixels, each pixel having a pixel value representative of a feature of a mask pattern. The image 1902 may be a rendered mask image of the curvilinear mask pattern 1901.

The method, in process P1903, involves generating, via a processor (e.g., processor 104), the level-set function by iteratively modifying the image pixels such that a difference between interpolated values on each point of the curvilinear mask pattern and the threshold value is reduced.

This could be represented by a cost function as given below:

$$f = w {\sum }_{i} {{w}_{i} ( ∅ ( {x}_{i} ) - C )}^{2}$$

In an embodiment, the generating of the level-set function involves identifying a set of locations along the curvilinear mask pattern, determining level-set function values using pixel values of the initial image interpolated at the set of locations, calculating the difference between the values and the threshold value C, and modifying one or more pixel values of pixels of the image such that the difference (e.g., the cost function f above) is reduced.

Referring back to FIG. 8, in an operation P802, the composite image 702a and the reference post-OPC image 712a are provided as input to the post-OPC image generator 450. The post-OPC image generator 450 generates a predicted post-OPC image 722a based on the composite image 702a. In some embodiments, the post-OPC image generator 450 is a machine learning model. In some embodiments, the machine learning model is implemented as a neural network (e.g., deep CNN).

In an operation P803, a cost function 803 of the post-OPC image generator 450 that is indicative of a difference between the predicted post-OPC image and the reference post-OPC image is determined.

In an operation P804, parameters of the post-OPC image generator 450 (e.g., weights or biases of the machine learning model) are adjusted such that the cost function 803 is reduced. The parameters may be adjusted in various ways. For example, the parameters may be adjusted based on a gradient descent method. In some embodiments, the input data of composite image 702a, reference post-OPC image 712a could actually be a set including multiple images of different clips/locations.

In an operation P805, a determination is made as to whether a training condition is satisfied. If the training condition is not satisfied, the process 800 is executed again with the same images or a next composite image 702b and a reference post-OPC image 712b from the set of composite images 702 and the reference post-OPC images 712. The process 800 is executed with the same or a different composite image set and a reference post-OPC image iteratively until the training condition is satisfied. The training condition may be satisfied when the cost function 803 is minimized, the rate at which the cost function 803 reduces is below a threshold value, the process 800 (e.g., operations P801-P804) is executed for a predefined number of iterations, or other such conditions. The process 800 may conclude when the training condition is satisfied.

At the end of the training process (e.g., when the training condition is satisfied), the post-OPC image generator 450 may be used as a trained post-OPC image generator 450, and may be used to predict a post-OPC image for any unseen composite image.

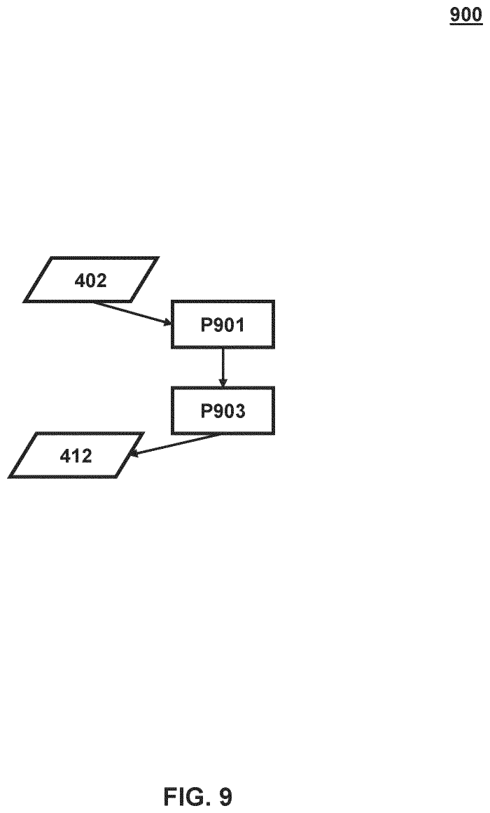

An example method employing the trained post-OPC image generator is discussed with respect to FIG. 9 below.

FIG. 9 is a flow chart of a method 900 for determining a post-OPC image for a mask, in accordance with one or more embodiments. In an operation P901, an input 402 that is representative of (a) a target pattern to be printed on a substrate and (b) reference layer patterns that are associated with the target pattern are obtained and provided to the trained post-OPC image generator 450. In some embodiments, the input 402 may include a collection of images 410 having an image of the target pattern, SRAF pattern image, SRIF pattern image, and an image of each of the reference layers patterns (e.g., context layer pattern image, dummy pattern image) as described at least with reference to FIGS. 4 and 5. In some embodiments, the input 402 may be a composite image 420 that is a combination of the target pattern image, SRAF pattern image, SRIF pattern image and the reference layer pattern images as described at least with reference to FIG. 6A.

In an operation P903, a post-OPC image 412 of the mask is generated by executing the trained post-OPC image generator 450 using the input 402. In some embodiments, the predicted post-OPC image 412 may be an image of a mask pattern corresponding to the target pattern. In some embodiments, the predicted post-OPC image 412 may be a reconstructed image of the mask pattern.

In an embodiment, the post-OPC images generated according to the method 900 may be employed in optimization of patterning process or adjusting parameters of the patterning process. In an embodiment, the predicted post-OPC images would be used to determine the edge or dissected edge movement amounts from the target patterns to make post-OPC patterns, while the determined mask patterns may be used directly as post-OPC mask, or having further OPC process to refine the performance to get to final post-OPC mask. This would help to reduce the computational resource needed to obtain the post-OPC mask of layouts. As an example, OPC addresses the fact that the final size and placement of an image of the design layout projected on the substrate will not be identical to, or simply depend only on the size and placement of the design layout on the patterning device. It is noted that the terms “mask”, “reticle”, “patterning device” are utilized interchangeably herein. Also, person skilled in the art will recognize that, especially in the context of lithography simulation/optimization, the term “mask”/“patterning device” and “design layout” can be used interchangeably, as in lithography simulation/optimization, a physical patterning device is not necessarily used but a design layout can be used to represent a physical patterning device. For the small feature sizes and high feature densities present on some design layout, the position of a particular edge of a given feature will be influenced to a certain extent by the presence or absence of other adjacent features. These proximity effects arise from minute amounts of radiation coupled from one feature to another and/or non-geometrical optical effects such as diffraction and interference. Similarly, proximity effects may arise from diffusion and other chemical effects during post-exposure bake (PEB), resist development, and etching that generally follow lithography.

In order to ensure that the projected image of the design layout is in accordance with requirements of a given target circuit design, proximity effects need to be predicted and compensated for, using sophisticated numerical models, corrections or pre-distortions of the design layout. The article “Full-Chip Lithography Simulation and Design Analysis—How OPC Is Changing IC Design”, C. Spence, Proc. SPIE, Vol. 5751, pp 1-14 (2005) provides an overview of current “model-based” optical proximity correction processes. In a typical high-end design almost every feature of the design layout has some modification in order to achieve high fidelity of the projected image to the target design. These modifications may include shifting or biasing of edge positions or line widths as well as application of “assist” features that are intended to assist projection of other features.

Application of model-based OPC to a target design involves good process models and considerable computational resources, given the many millions of features typically present in a chip design. However, applying OPC is generally not an “exact science”, but an empirical, iterative process that does not always compensate for all possible proximity effect. Therefore, effect of OPC, e.g., design layouts after application of OPC and any other RET, need to be verified by design inspection, i.e., intensive full-chip simulation using calibrated numerical process models, in order to minimize the possibility of design flaws being built into the patterning device pattern. This is driven by the enormous cost of making high-end patterning devices, which run in the multi-million-dollar range, as well as by the impact on turn-around time by reworking or repairing actual patterning devices once they have been manufactured.

Both OPC and full-chip RET verification may be based on numerical modeling systems and methods as described, for example in, U.S. patent application Ser. No. 10/815,573 and an article titled “Optimized Hardware and Software For Fast, Full Chip Simulation”, by Y. Cao et al., Proc. SPIE, Vol. 5754, 405 (2005).

One RET is related to adjustment of the global bias of the design layout. The global bias is the difference between the patterns in the design layout and the patterns intended to print on the substrate. For example, a circular pattern of 25 nm diameter may be printed on the substrate by a 50 nm diameter pattern in the design layout or by a 20 nm diameter pattern in the design layout but with high dose.

In addition to optimization to design layouts or patterning devices (e.g., OPC), the illumination source can also be optimized, either jointly with patterning device optimization or separately, in an effort to improve the overall lithography fidelity. The terms “illumination source” and “source” are used interchangeably in this document. Since the 1990s, many off-axis illumination sources, such as annular, quadrupole, and dipole, have been introduced, and have provided more freedom for OPC design, thereby improving the imaging results, As is known, off-axis illumination is a proven way to resolve fine structures (i.e., target features) contained in the patterning device. However, when compared to a traditional illumination source, an off-axis illumination source usually provides less radiation intensity for the aerial image (AI). Thus, it becomes desirable to attempt to optimize the illumination source to achieve the optimal balance between finer resolution and reduced radiation intensity.

Numerous illumination source optimization approaches can be found, for example, in an article by Rosenbluth et al., titled “Optimum Mask and Source Patterns to Print A Given Shape”, Journal of Microlithography, Microfabrication, Microsystems 1(1), pp.13-20, (2002). The source is partitioned into several regions, each of which corresponds to a certain region of the pupil spectrum. Then, the source distribution is assumed to be uniform in each source region and the brightness of each region is optimized for process window. However, such an assumption that the source distribution is uniform in each source region is not always valid, and as a result the effectiveness of this approach suffers. In another example set forth in an article by Granik, titled “Source Optimization for Image Fidelity and Throughput”, Journal of Microlithography, Microfabrication, Microsystems 3(4), pp.509-522, (2004), several existing source optimization approaches are overviewed, and a method based on illuminator pixels is proposed that converts the source optimization problem into a series of non-negative least square optimizations. Though these methods have demonstrated some successes, they typically require multiple complicated iterations to converge. In addition, it may be difficult to determine the appropriate/optimal values for some extra parameters, such as γ in Granik's method, which dictates the trade-off between optimizing the source for substrate image fidelity and the smoothness requirement of the source.

For low k₁ photolithography, optimization of both the source and patterning device is useful to ensure a viable process window for projection of critical circuit patterns. Some algorithms (e.g., Socha et. al. Proc. SPIE vol. 5853, 2005, p.180) discretize illumination into independent source points and mask into diffraction orders in the spatial frequency domain, and separately formulate a cost function (which is defined as a function of selected design variables) based on process window metrics such as exposure latitude which could be predicted by optical imaging models from source point intensities and patterning device diffraction orders. The term “design variables” as used herein comprises a set of parameters of a lithographic projection apparatus or a lithographic process, for example, parameters a user of the lithographic projection apparatus can adjust, or image characteristics a user can adjust by adjusting those parameters. It should be appreciated that any characteristics of a lithographic projection process, including those of the source, the patterning device, the projection optics, and/or resist characteristics can be among the design variables in the optimization. The cost function is often a non-linear function of the design variables. Then standard optimization techniques are used to minimize the cost function.

Relatedly, the pressure of ever decreasing design rules have driven semiconductor chipmakers to move deeper into the low IQ lithography era with existing 193 nm ArF lithography. Lithography towards lower IQ puts heavy demands on RET, exposure tools, and the need for litho-friendly design. 1.35 ArF hyper numerical aperture (NA) exposure tools may be used in the future. To help ensure that circuit design can be produced on to the substrate with workable process window, source-patterning device optimization (referred to herein as source-mask optimization or SMO) is becoming a significant RET for 2× nm node.

A source and patterning device (design layout) optimization method and system that allows for simultaneous optimization of the source and patterning device using a cost function without constraints and within a practicable amount of time is described in a commonly assigned International

Patent Application No. PCT/US2009/065359, filed on Nov. 20, 2009, and published as WO2010/059954, titled “Fast Freeform Source and Mask Co-Optimization Method”, which is hereby incorporated by reference in its entirety.

Another source and mask optimization method and system that involves optimizing the source by adjusting pixels of the source is described in a commonly assigned U.S. patent application Ser. No. 12/813456, filed on Jun. 10, 2010, and published as U.S. Patent Application Publication No. 2010/0315614, titled “Source-Mask Optimization in Lithographic Apparatus”, which is hereby incorporated by reference in its entirety.

In a lithographic projection apparatus, as an example, a cost function is expressed as

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) \qquad ( Eq . 1 )$$

wherein ( [symbol] ₁, [symbol] ₂ . . . , [symbol] _{N}) are N design variables or values thereof. fₚ( [symbol] ₁, [symbol] ₂, . . . , [symbol] _{N}) can be a function of the design variables ( [symbol] ₁, [symbol] ₂, . . . , [symbol] _{N})) such as a difference between an actual value and an intended value of a characteristic at an evaluation point for a set of values of the design variables of ( [symbol] ₁, [symbol] ₂, . . . , [symbol] _{N}). wₚ is a weight constant associated with fₚ( [symbol] ₁, [symbol] ₂, . . . , [symbol] _{N}) . An evaluation point or pattern more critical than others can be assigned a higher wₚ value. Patterns and/or evaluation points with larger number of occurrences may be assigned a higher wₚ value, too. Examples of the evaluation points can be any physical point or pattern on the substrate, any point on a virtual design layout, or resist image, or aerial image, or a combination thereof. fₚ( [symbol] ₁, [symbol] ₂, . . . [symbol] _{N}) can also be a function of one or more stochastic effects such as the LWR, which are functions of the design variables ( [symbol] ₁, [symbol] ₂, . . . , [symbol] _{N}). The cost function may represent any suitable characteristics of the lithographic projection apparatus or the substrate, for instance, failure rate of a feature, focus, CD, image shift, image distortion, image rotation, stochastic effects, throughput, CDU, or a combination thereof. CDU is local CD variation (e.g., three times of the standard deviation of the local CD distribution). CDU may be interchangeably referred to as LCDU. In one embodiment, the cost function represents (i.e., is a function of) CDU, throughput, and the stochastic effects. In one embodiment, the cost function represents (i.e., is a function of) EPE, throughput, and the stochastic effects. In one embodiment, the design variables ( [symbol] ₁, [symbol] ₂, . . . , [symbol] _{N}) comprise dose, global bias of the patterning device, shape of illumination from the source, or a combination thereof. Since it is the resist image that often dictates the circuit pattern on a substrate, the cost function often includes functions that represent some characteristics of the resist image. For example, fₚ( [symbol] ₁, [symbol] ₂, . . . , [symbol] _{N}) of such an evaluation point can be simply a distance between a point in the resist image to an intended position of that point (i.e., edge placement error EPEₚ( [symbol] ₁, [symbol] ₂, . . . , [symbol] _{N})). The design variables can be any adjustable parameters such as adjustable parameters of the source, the patterning device, the projection optics, dose, focus, etc. The projection optics may include components collectively called as “wavefront manipulator” that can be used to adjust shapes of a wavefront and intensity distribution and/or phase shift of the irradiation beam. The projection optics preferably can adjust a wavefront and intensity distribution at any location along an optical path of the lithographic projection apparatus, such as before the patterning device, near a pupil plane, near an image plane, near a focal plane. The projection optics can be used to correct or compensate for certain distortions of the wavefront and intensity distribution caused by, for example, the source, the patterning device, temperature variation in the lithographic projection apparatus, thermal expansion of components of the lithographic projection apparatus. Adjusting the wavefront and intensity distribution can change values of the evaluation points and the cost function. Such changes can be simulated from a model or actually measured. Of course, CF ( [symbol] ₁, [symbol] ₂, . . . , [symbol] _{N}) is not limited the form in Eq. 1. CF ( [symbol] ₁, [symbol] ₂, . . . , [symbol] _{N}) can be in any other suitable form.

It should be noted that the normal weighted root mean square (RMS) of fₚ( [symbol] ₁, [symbol] ₂, . . . , [symbol] _{N}) is defined as

$$\\ \sqrt{\frac{1}{P} {\sum }_{p = 1}^{P} {w}_{p} {f}_{p}^{2} ( {𝓏}_{1} , {𝓏}_{2} , … , {𝓏}_{N} )} ,$$

therefore, minimizing the weighted RMS of fₚ( [symbol] ₁, [symbol] ₂, . . . , [symbol] _{N}) is equivalent to minimizing the cost function

$$\\ CF ( {𝓏}_{1} , {𝓏}_{2} , … , {𝓏}_{N} ) = {\sum }_{p = 1}^{P} {w}_{p} {f}_{p}^{2} ( {𝓏}_{1} , {𝓏}_{2} , … , {𝓏}_{N} ) ,$$

defined in Eq. 1. Thus, the weighted RMS of fₚ( [symbol] ₁, [symbol] ₂, . . . , [symbol] _{N}) and Eq. 1 may be utilized interchangeably for notational simplicity herein.

Further, if considering maximizing the PW (Process Window), one can consider the same physical location from different PW conditions as different evaluation points in the cost function in (Eq. 1). For example, if considering N PW conditions, then one can categorize the evaluation points according to their PW conditions and write the cost functions as:

$$\\ \begin{matrix}CF ( {𝓏}_{1} , {𝓏}_{2} , … , {𝓏}_{N} ) = {\sum }_{p = 1}^{P} {w}_{p} {f}_{p}^{2} ( {𝓏}_{1} , {𝓏}_{2} , … , {𝓏}_{N} ) = {\sum }_{u = 1}^{U} {\sum }_{{p}_{u} = 1}^{{P}_{u}} {w}_{{p}_{u}} {f}_{{p}_{u}}^{2} ( {𝓏}_{1} , {𝓏}_{2} , … , 𝓏 ) & ( Eq . {1}^{′} )\end{matrix}$$

Where fₚ_{ᵤ}( [symbol] , [symbol] ₂, . . . , [symbol] _{N}) is the value of fₚ( [symbol] ₁, [symbol] ₂, . . . , [symbol] _{N}) under the u-th PW condition u=1, . . . , U. When fₚ( [symbol] ₁, [symbol] ₂, . . . , [symbol] _{N}) is the EPE, then minimizing the above cost function is equivalent to minimizing the edge shift under various PW conditions, thus this leads to maximizing the PW. In particular, if the PW also consists of different mask bias, then minimizing the above cost function also includes the minimization of MEEF (Mask Error Enhancement Factor), which is defined as the ratio between the substrate EPE and the induced mask edge bias.

The design variables may have constraints, which can be expressed as ( [symbol] ₁, [symbol] ₂, . . . , [symbol] _{N})∈ Z, where Z is a set of possible values of the design variables. One possible constraint on the design variables may be imposed by a desired throughput of the lithographic projection apparatus. The desired throughput may limit the dose and thus has implications for the stochastic effects (e.g., imposing a lower bound on the stochastic effects). Higher throughput generally leads to lower dose, shorter longer exposure time and greater stochastic effects. Consideration of substrate throughput and minimization of the stochastic effects may constrain the possible values of the design variables because the stochastic effects are function of the design variables. Without such a constraint imposed by the desired throughput, the optimization may yield a set of values of the design variables that are unrealistic. For example, if the dose is among the design variables, without such a constraint, the optimization may yield a dose value that makes the throughput economically impossible. However, the usefulness of constraints should not be interpreted as a necessity. The throughput may be affected by the failure rate-based adjustment to parameters of the patterning process. It is desirable to have lower failure rate of the feature while maintaining a high throughput. Throughput may also be affected by the resist chemistry. Slower resist (e.g., a resist that requires higher amount of light to be properly exposed) leads to lower throughput. Thus, based on the optimization process involving failure rate of a feature due to resist chemistry or fluctuations, and dose requirements for higher throughput, appropriate parameters of the patterning process may be determined.

The optimization process therefore is to find a set of values of the design variables, under the constraints ( [symbol] ₁, [symbol] ₂, . . . , [symbol] _{N})∈ Z, that minimize the cost function, i.e., to find

$$\\ \begin{matrix}( {\tilde{𝓏}}_{1} , {\tilde{𝓏}}_{2} , … {\tilde{𝓏}}_{N} ) = {arg min}_{( {𝓏}_{1} , {𝓏}_{2} , … , {𝓏}_{N} ) ∈ Z} CF ( {𝓏}_{1} , {𝓏}_{2} , … , {𝓏}_{N} ) = {arg min}_{( {𝓏}_{1} , {𝓏}_{2} , … , {𝓏}_{N} ) ∈ Z} {\sum }_{p = 1}^{P} {w}_{p} {f}_{p}^{2} ( {𝓏}_{1} , {𝓏}_{2} , … , {𝓏}_{N} ) & ( Eq . 2 )\end{matrix}$$

A general method of optimizing the lithography projection apparatus, according to an embodiment, is illustrated in FIG. 10. This method comprises a step S1202 of defining a multi-variable cost function of a plurality of design variables. The design variables may comprise any suitable combination selected from characteristics of the illumination source (1200A) (e.g., pupil fill ratio, namely percentage of radiation of the source that passes through a pupil or aperture), characteristics of the projection optics (1200B) and characteristics of the design layout (1200C). For example, the design variables may include characteristics of the illumination source (1200A) and characteristics of the design layout (1200C) (e.g., global bias) but not characteristics of the projection optics (1200B), which leads to an SMO. Alternatively, the design variables may include characteristics of the illumination source (1200A), characteristics of the projection optics (1200B) and characteristics of the design layout (1200C), which leads to a source-mask-lens optimization (SMLO). In step S1204, the design variables are simultaneously adjusted so that the cost function is moved towards convergence.

In step S1206, it is determined whether a predefined termination condition is satisfied. The predetermined termination condition may include various possibilities, i.e., the cost function may be minimized or maximized, as required by the numerical technique used, the value of the cost function has been equal to a threshold value or has crossed the threshold value, the value of the cost function has reached within a preset error limit, or a preset number of iterations is reached. If either of the conditions in step S1206 is satisfied, the method ends. If none of the conditions in step S1206 is satisfied, the step S1204 and S1206 are iteratively repeated until a desired result is obtained. The optimization does not necessarily lead to a single set of values for the design variables because there may be physical restraints caused by factors such as the failure rates, the pupil fill factor, the resist chemistry, the throughput, etc. The optimization may provide multiple sets of values for the design variables and associated performance characteristics (e.g., the throughput) and allows a user of the lithographic apparatus to pick one or more sets.

In a lithographic projection apparatus, the source, patterning device and projection optics can be optimized alternatively (referred to as Alternative Optimization) or optimized simultaneously (referred to as Simultaneous Optimization). The terms “simultaneous”, “simultaneously”, “joint” and “jointly” as used herein mean that the design variables of the characteristics of the source, patterning device, projection optics and/or any other design variables, are allowed to change at the same time. The term “alternative” and “alternatively” as used herein mean that not all of the design variables are allowed to change at the same time.

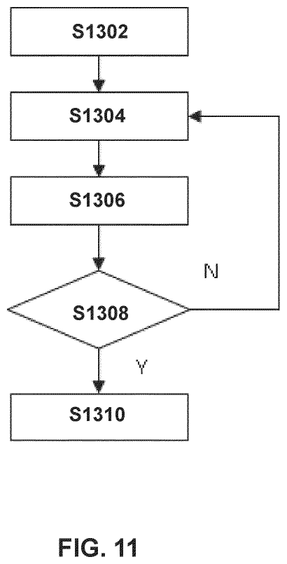

In FIG. 11, the optimization of all the design variables is executed simultaneously. Such flow may be called the simultaneous flow or co-optimization flow. Alternatively, the optimization of all the design variables is executed alternatively, as illustrated in FIG. 11. In this flow, in each step, some design variables are fixed while the other design variables are optimized to minimize the cost function; then in the next step, a different set of variables are fixed while the others are optimized to minimize the cost function. These steps are executed alternatively until convergence or certain terminating conditions are met.

As shown in the non-limiting example flowchart of FIG. 11, first, a design layout (step S1302) is obtained, then a step of source optimization is executed in step S1304, where all the design variables of the illumination source are optimized (SO) to minimize the cost function while all the other design variables are fixed. Then in the next step S1306, a mask optimization (MO) is performed, where all the design variables of the patterning device are optimized to minimize the cost function while all the other design variables are fixed. These two steps are executed alternatively, until certain terminating conditions are met in step S1308. Various termination conditions can be used, such as, the value of the cost function becomes equal to a threshold value, the value of the cost function crosses the threshold value, the value of the cost function reaches within a preset error limit, or a preset number of iterations is reached, etc. Note that SO-MO-Alternative-Optimization is used as an example for the alternative flow. The alternative flow can take many different forms, such as SO-LO-MO-Alternative-Optimization, where SO, LO (Lens Optimization) is executed, and MO alternatively and iteratively; or first SMO can be executed once, then execute LO and MO alternatively and iteratively; and so on. Finally, the output of the optimization result is obtained in step S1310, and the process stops.

The pattern selection algorithm, as discussed before, may be integrated with the simultaneous or alternative optimization. For example, when an alternative optimization is adopted, first a full-chip SO can be performed, the ‘hot spots’ and/or ‘warm spots’ are identified, then an MO is performed. In view of the present disclosure numerous permutations and combinations of sub-optimizations are possible in order to achieve the desired optimization results.

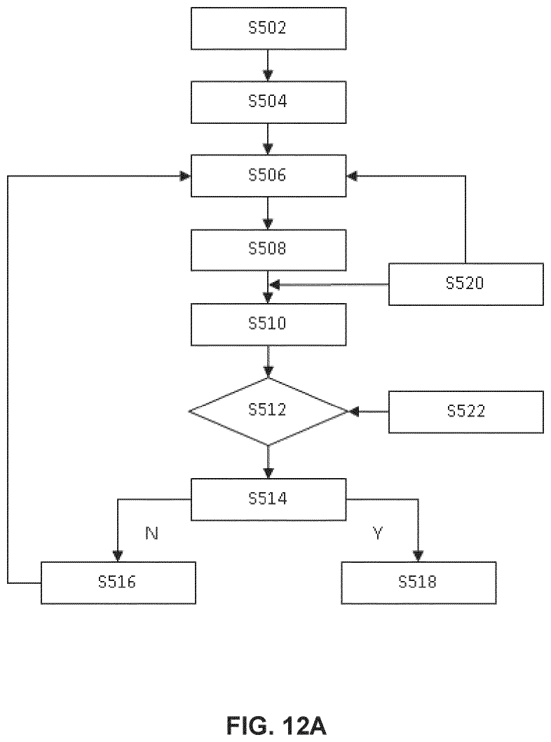

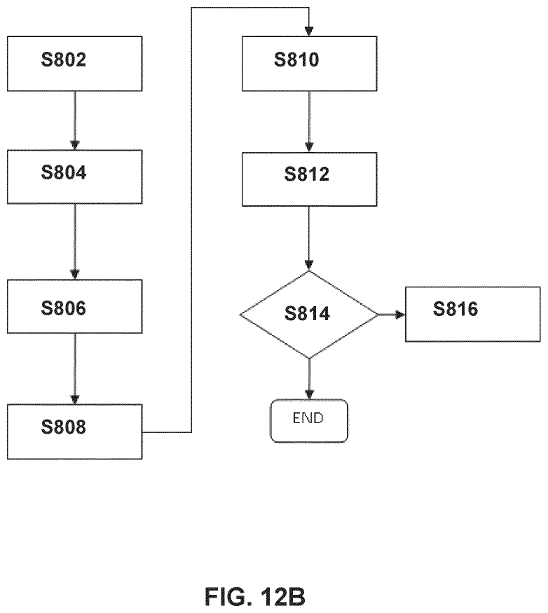

FIG. 12A shows one exemplary method of optimization, where a cost function is minimized In step S502, initial values of design variables are obtained, including their tuning ranges, if any. In step S504, the multi-variable cost function is set up. In step S506, the cost function is expanded within a small enough neighborhood around the starting point value of the design variables for the first iterative step (i=0). In step S508, standard multi-variable optimization techniques are applied to minimize the cost function. Note that the optimization problem can apply constraints, such as tuning ranges, during the optimization process in S508 or at a later stage in the optimization process. Step S520 indicates that each iteration is done for the given test patterns (also known as “gauges”) for the identified evaluation points that have been selected to optimize the lithographic process. In step S510, a lithographic response is predicted. In step S512, the result of step S510 is compared with a desired or ideal lithographic response value obtained in step S522. If the termination condition is satisfied in step S514, i.e., the optimization generates a lithographic response value sufficiently close to the desired value, and then the final value of the design variables is outputted in step S518. The output step may also include outputting other functions using the final values of the design variables, such as outputting a wavefront aberration-adjusted map at the pupil plane (or other planes), an optimized source map, and optimized design layout etc. If the termination condition is not satisfied, then in step S516, the values of the design variables is updated with the result of the i-th iteration, and the process goes back to step S506. The process of FIG. 12A is elaborated in detail below.

In an exemplary optimization process, no relationship between the design variables ( [symbol] ₁, [symbol] ₂, . . . , [symbol] _{N}) and fₚ( [symbol] ₁, [symbol] ₂, . . . , [symbol] _{N}) is assumed or approximated, except that fₚ( [symbol] ₁, [symbol] ₂, . . . , [symbol] _{N}) is sufficiently smooth (e.g., first order derivatives

$$\\ \frac{\partial {f}_{p} ( {𝓏}_{1} , {𝓏}_{2} , … , {𝓏}_{N} )}{\partial {𝓏}_{n}} ,$$

(n=1, 2, . . . N) exist), which is generally valid in a lithographic projection apparatus. An algorithm, such as the Gauss—Newton algorithm, the Levenberg-Marquardt algorithm, the gradient descent algorithm, simulated annealing, the genetic algorithm, can be applied to find ( [symbol] ₁, [symbol] ₂, . . . , [symbol] _{N}).

Here, the Gauss—Newton algorithm is used as an example. The Gauss—Newton algorithm is an iterative method applicable to a general non-linear multi-variable optimization problem. In the i-th iteration wherein the design variables ( [symbol] ₁, [symbol] ₂, . . . , [symbol] _{N}) take values of ( [symbol] ₁ᵢ, [symbol] ₂ᵢ, . . . , [symbol] _{Ni}), the Gauss- Newton algorithm linearizes fₚ( [symbol] ₁, [symbol] ₂, . . . , [symbol] _{N}) in the vicinity of ( [symbol] ₁ᵢ, [symbol] ₂ᵢ, . . . , [symbol] _{Ni}) and then calculates values ( [symbol] ₁₍ᵢ₊₁₎, [symbol] ₂₍ᵢ₊₁₎, . . . , [symbol] _{N(i+1)}) in the vicinity of ( [symbol] ₁ᵢ, [symbol] ₂ᵢ, . . . , [symbol] _{Ni}) that give a minimum of CF ( [symbol] ₁, [symbol] ₂, . . . , [symbol] _{N}). The design variables ( [symbol] ₁, [symbol] ₂, . . . , [symbol] _{N}) take the values of ( [symbol] ₁₍ᵢ₊₁₎, [symbol] ₂₍ᵢ₊₁₎, . . . , [symbol] _{N(i+1)}) in the (i+1)-th iteration. This iteration continues until convergence (i.e., CF ( [symbol] ₁, [symbol] ₂, . . . , [symbol] _{N}) does not reduce any further) or a preset number of iterations is reached.

Specifically, in the i-th iteration, in the vicinity of ( [symbol] ₁ᵢ, [symbol] ₂ᵢ, . . . , [symbol] _{Ni}),

$$\\ \begin{matrix}{f}_{p} ( {𝓏}_{1} , {𝓏}_{2} , … , {𝓏}_{N} ) \approx {f}_{p} ( {𝓏}_{1 i} , {𝓏}_{2 i} , … , {𝓏}_{Ni} ) + {\sum }_{n = 1}^{N} \frac{\partial {f}_{p} ( {𝓏}_{1} , {𝓏}_{2} , … , {𝓏}_{N} )}{\partial {𝓏}_{n}} {\vert}_{{{𝓏}_{1} = {𝓏}_{1 i ,} {𝓏}_{2} = {𝓏}_{2 i ,} … , {𝓏}_{N} = {𝓏}_{Ni ,}}^{{}^{}}} ( {𝓏}_{n} - {𝓏}_{ni} ) & ( Eq . 3 )\end{matrix}$$

Under the approximation of Eq. 3, the cost function becomes:

$$\\ \begin{matrix}CF ( {𝓏}_{1} , {𝓏}_{2} , … , {𝓏}_{N} ) = {\sum }_{p = 1}^{P} {w}_{p} {f}_{p}^{2} ( {𝓏}_{1} , {𝓏}_{2} , … , {𝓏}_{N} ) = {\sum }_{p = 1}^{P} {{w}_{p} ( {f}_{p} ( {𝓏}_{1 i} , {𝓏}_{2 i} , … , {𝓏}_{Ni} ) + {\sum }_{n = 1}^{N} \frac{\partial {f}_{p} ( {𝓏}_{1} , {𝓏}_{2} , … , {𝓏}_{N} )}{\partial {𝓏}_{n}} {\vert}_{{{𝓏}_{1} = {𝓏}_{1 i ,} {𝓏}_{2} = {𝓏}_{2 i ,} … , {𝓏}_{N} = {𝓏}_{Ni ,}}^{{}^{}}} ( {𝓏}_{n} - {𝓏}_{ni} ) )}^{2} & ( Eq . 4 )\end{matrix}$$

which is a quadratic function of the design variables ( [symbol] ₁, [symbol] ₂, . . . , [symbol] _{N}). Every term is constant except the design variables ( [symbol] ₁, [symbol] ₂, . . . , [symbol] _{N}).

If the design variables ( [symbol] ₁, [symbol] ₂, . . . , [symbol] _{N}) are not under any constraints, ( [symbol] ₁₍ᵢ₊₁₎), [symbol] ₂₍ᵢ₊₁₎, . . . , [symbol] _{N(i+1)}) can be derived by solving by N linear equations:

$$\\ \frac{\partial CF ( {𝓏}_{1} , {𝓏}_{2} , … , {𝓏}_{N} )}{\partial {𝓏}_{n}} = 0 , wherein n = 1 , 2 , … N .$$

If the design variables ( [symbol] ₁, [symbol] ₂, . . . , [symbol] _{N}) are under the constraints in the form of J inequalities (e.g., tuning ranges of

$$\\ ( {𝓏}_{1} , {𝓏}_{2} , … , {𝓏}_{N} ) ) {\sum }_{n = 1}^{N} {A}_{nj} {𝓏}_{n} \leq {B}_{j} ,$$

for j=1, 2, . . . J; and K equalities (e.g., interdependence between the design variables)

$$\\ {\sum }_{n = 1}^{N} {C}_{nk} {𝓏}_{n} = {D}_{k} ,$$

for k=1, 2, . . . K; the optimization process becomes a classic quadratic programming problem, wherein Aₙⱼ, Bⱼ, Cₙₖ, Dₖ are constants. Additional constraints can be imposed for each iteration. For example, a “damping factor” Δ_{D} can be introduced to limit the difference between ( [symbol] ₁₍ᵢ₊₁₎, [symbol] ₂₍ᵢ₊₁₎, . . . , [symbol] _{N(i+1)}) and ( [symbol] ₁ᵢ, [symbol] ₂ᵢ, . . . , [symbol] _{Ni}) , so that the approximation of Eq. 3 holds. Such constraints can be expressed as ′ₙᵢ−Δ_{D}≤ [symbol] ₙ≤ [symbol] ₙᵢ+Δ_{D}. ( [symbol] ₁₍ᵢ₊₁₎, [symbol] ₂₍ᵢ₊₁₎, . . . , [symbol] _{N(i+1)}) can be derived using, for example, methods described in Numerical Optimization (2^{nd} ed.) by Jorge Nocedal and Stephen J. Wright (Berlin New York: Vandenberghe. Cambridge University Press).

Instead of minimizing the RMS of fₚ( [symbol] ₁, [symbol] ₂, . . . , [symbol] _{N}) , the optimization process can minimize magnitude of the largest deviation (the worst defect) among the evaluation points to their intended values. In this approach, the cost function can alternatively be expressed as

$$\\ \begin{matrix}CF ( {𝓏}_{1} , {𝓏}_{2} , … , {𝓏}_{N} ) = {max}_{1 \leq p \leq P} \frac{{f}_{p} ( {𝓏}_{1} , {𝓏}_{2} , … , {𝓏}_{N} )}{{CL}_{p}} , & ( Eq . 5 )\end{matrix}$$

wherein CLₚ is the maximum allowed value for fₚ( [symbol] ₁, [symbol] ₂, . . . , [symbol] _{N}) . This cost function represents the worst defect among the evaluation points. Optimization using this cost function minimizes magnitude of the worst defect. An iterative greedy algorithm can be used for this optimization.

The cost function of Eq. 5 can be approximated as:

$$\\ \begin{matrix}CF ( {𝓏}_{1} , {𝓏}_{2} , … , {𝓏}_{N} ) = {\sum }_{p = 1}^{P} {( \frac{{f}_{p} ( {𝓏}_{1} , {𝓏}_{2} , … , {𝓏}_{N} )}{{CL}_{p}} )}^{q} , & ( Eq . 6 )\end{matrix}$$

wherein q is an even positive integer such as at least 4, preferably at least 10. Eq 6 mimics the behavior of Eq. 5, while allowing the optimization to be executed analytically and accelerated by using methods such as the deepest descent method, the conjugate gradient method, etc.

Minimizing the worst defect size can also be combined with linearizing of fₚ( [symbol] ₁, [symbol] ₂, . . . , [symbol] _{N}) . Specifically, f p ( [symbol] ₁, [symbol] ₂, . . . , [symbol] _{N}) is approximated as in Eq. 3. Then the constraints on worst defect size are written as inequalities E_{Lp}≤fₚ( [symbol] ₁, [symbol] ₂, . . . , [symbol] _{N})≤E_{Up}, wherein E_{Lp} and E_{Up} are two constants specifying the minimum and maximum allowed deviation for the fₚ( [symbol] ₁, [symbol] ₂, . . . , [symbol] _{N}). Plugging Eq. 3 in, these constraints are transformed to, for p=1, . . . P,

$$\\ \begin{matrix}{\sum }_{n = 1}^{N} \frac{\partial {f}_{p} ( {𝓏}_{1} , {𝓏}_{2} , … , {𝓏}_{N} )}{\partial {𝓏}_{n}} {\vert}_{{{𝓏}_{1} = {𝓏}_{1 i ,} {𝓏}_{2} = {𝓏}_{2 i ,} … , {𝓏}_{N} = {𝓏}_{Ni ,}}^{{}^{}}} {𝓏}_{n} \leq {E}_{Up} + {\sum }_{n = 1}^{N} \frac{\partial {f}_{p} ( {𝓏}_{1} , {𝓏}_{2} , … , {𝓏}_{N} )}{\partial {𝓏}_{n}} {\vert}_{{{𝓏}_{1} = {𝓏}_{1 i ,} {𝓏}_{2} = {𝓏}_{2 i ,} … , {𝓏}_{N} = {𝓏}_{Ni ,}}^{{}^{}}} {𝓏}_{ni} - {f}_{p} ( {𝓏}_{1 i} , {𝓏}_{2 i} , … , {𝓏}_{Ni} ) and & ( Eq . {6}^{′} )\end{matrix}$$

$$\\ \begin{matrix}- {\sum }_{n = 1}^{N} \frac{\partial {f}_{p} ( {𝓏}_{1} , {𝓏}_{2} , … , {𝓏}_{N} )}{\partial {𝓏}_{n}} {\vert}_{{{𝓏}_{1} = {𝓏}_{1 i ,} {𝓏}_{2} = {𝓏}_{2 i ,} … , {𝓏}_{N} = {𝓏}_{Ni ,}}^{{}^{}}} {𝓏}_{n} \leq - {E}_{Up} - {\sum }_{n = 1}^{N} \frac{\partial {f}_{p} ( {𝓏}_{1} , {𝓏}_{2} , … , {𝓏}_{N} )}{\partial {𝓏}_{n}} {\vert}_{{{𝓏}_{1} = {𝓏}_{1 i ,} {𝓏}_{2} = {𝓏}_{2 i ,} … , {𝓏}_{N} = {𝓏}_{Ni ,}}^{{}^{}}} {𝓏}_{ni} + {f}_{p} ( {𝓏}_{1 i} , {𝓏}_{2 i} , … , {𝓏}_{Ni} ) & ( Eq . {6}^{″} )\end{matrix}$$

Since Eq. 3 is generally valid only in the vicinity of ( [symbol] ₁ᵢ, [symbol] ₂ᵢ, . . . , [symbol] _{Ni}) , in case the desired constraints E_{Lp}≤fₚ( [symbol] ₁, [symbol] ₂, . . . , [symbol] _{N})≤E_{Up} cannot be achieved in such vicinity, which can be determined by any conflict among the inequalities, the constants E LP and E Up can be relaxed until the constraints are achievable. This optimization process minimizes the worst defect size in the vicinity of ( [symbol] ₁ᵢ, [symbol] ₂ᵢ, . . . , [symbol] _{Ni}). Then each step reduces the worst defect size gradually, and each step is executed iteratively until certain terminating conditions are met. This will lead to optimal reduction of the worst defect size.

Another way to minimize the worst defect is to adjust the weight wₚ in each iteration. For example, after the i-th iteration, if the r-th evaluation point is the worst defect, wᵣ can be increased in the (i+1)-th iteration so that the reduction of that evaluation point's defect size is given higher priority.

In addition, the cost functions in Eq. 4 and Eq. 5 can be modified by introducing a

Lagrange multiplier to achieve compromise between the optimization on RMS of the defect size and the optimization on the worst defect size, i.e.,

$$\\ \begin{matrix}CF ( {𝓏}_{1} , {𝓏}_{2} , … , {𝓏}_{N} ) = ( 1 - λ ) {\sum }_{p = 1}^{P} {w}_{p} {f}_{p}^{2} ( {𝓏}_{1} , {𝓏}_{2} , … , {𝓏}_{N} ) + λ {max}_{1 \leq p \leq P} \frac{{f}_{p} ( {𝓏}_{1} , {𝓏}_{2} , … , {𝓏}_{N} )}{{CL}_{p}} & ( Eq . {6}^{′ ′ ′} )\end{matrix}$$

where λ is a preset constant that specifies the trade-off between the optimization on RMS of the defect size and the optimization on the worst defect size. In particular, if λ=0, then this becomes Eq. 4 and the RMS of the defect size is only minimized; while if λ=1, then this becomes Eq. 5 and the worst defect size is only minimized; if 0<λ<1, then both are taken into consideration in the optimization. Such optimization can be solved using multiple methods. For example, the weighting in each iteration may be adjusted, similar to the one described previously. Alternatively, similar to minimizing the worst defect size from inequalities, the inequalities of Eq. 6′ and 6″ can be viewed as constraints of the design variables during solution of the quadratic programming problem. Then, the bounds on the worst defect size can be relaxed incrementally or increase the weight for the worst defect size incrementally, compute the cost function value for every achievable worst defect size, and choose the design variable values that minimize the total cost function as the initial point for the next step. By doing this iteratively, the minimization of this new cost function can be achieved.

Optimizing a lithographic projection apparatus can expand the process window. A larger process window provides more flexibility in process design and chip design. The process window can be defined as a set of focus and dose values for which the resist image is within a certain limit of the design target of the resist image. Note that all the methods discussed here may also be extended to a generalized process window definition that can be established by different or additional base parameters in addition to exposure dose and defocus. These may include, but are not limited to, optical settings such as NA, sigma, aberrations, polarization, or optical constants of the resist layer. For example, as described earlier, if the PW also consists of different mask bias, then the optimization includes the minimization of MEEF (Mask Error Enhancement Factor), which is defined as the ratio between the substrate EPE and the induced mask edge bias. The process window defined on focus and dose values only serve as an example in this disclosure. A method of maximizing the process window, according to an embodiment, is described below.

In a first step, starting from a known condition (f₀, ε₀) in the process window, wherein f₀ is a nominal focus and eo is a nominal dose, minimizing one of the cost functions below in the vicinity (f₀±Δf, ε₀±Δε):

$$\\ \begin{matrix}CF ( {𝓏}_{1} , {𝓏}_{2} , … , {𝓏}_{N} , {f}_{0} , {ε}_{0} ) = {max}_{( f , ε ) = ( {f}_{0} \pm Δ f , {ε}_{0} \pm Δ ε )} {max}_{p} \vert {f}_{p} ( {𝓏}_{1} , {𝓏}_{2} , … , {𝓏}_{N} , f , ε ) \vert . & ( Eq . 7 )\end{matrix}$$

$$\\ or$$

$$\\ \begin{matrix}CF ( {𝓏}_{1} , {𝓏}_{2} , … , {𝓏}_{N} , {f}_{0} , {ε}_{0} ) = {\sum }_{( f , ε ) = ( {f}_{0} \pm Δ f , {ε}_{0} \pm Δ ε )} {\sum }_{p} {w}_{p} {f}_{p}^{2} ( {𝓏}_{1} , {𝓏}_{2} , … , {𝓏}_{N} , f , ε ) & ( Eq . {7}^{′} )\end{matrix}$$

$$\\ or$$

$$\\ \begin{matrix}CF ( {𝓏}_{1} , {𝓏}_{2} , … , {𝓏}_{N} , {f}_{0} , {ε}_{0} ) = ( 1 - λ ) {\sum }_{( f , ε ) = ( {f}_{0} \pm Δ f , {ε}_{0} \pm Δ ε )} {\sum }_{p} {w}_{p} {f}_{p}^{2} ( {𝓏}_{1} , {𝓏}_{2} , … , {𝓏}_{N} , f , ε ) + λ {max}_{( f , ε ) = ( {f}_{0} \pm Δ f , {ε}_{0} \pm Δ ε )} {max}_{p} \vert {f}_{p} ( {𝓏}_{1} , {𝓏}_{2} , … , {𝓏}_{N} , f , ε ) \vert & ( Eq . {7}^{″} )\end{matrix}$$

If the nominal focus f₀ and nominal dose ε₀ are allowed to shift, they can be optimized jointly with the design variables ( [symbol] ₁, [symbol] ₂, . . . , [symbol] _{N}). In the next step, (f₀±AΔf, ε₀±Δε) is accepted as part of the process window, if a set of values of ( [symbol] ₁, [symbol] ₂, . . . , [symbol] _{N},f, ε) can be found such that the cost function is within a preset limit.

Alternatively, if the focus and dose are not allowed to shift, the design variables ( [symbol] ₁, [symbol] ₂, . . . , [symbol] _{N}) are optimized with the focus and dose fixed at the nominal focus f₀ and nominal dose ε₀. In an alternative embodiment, (f₀±Δf, ε₀±Δε) is accepted as part of the process window, if a set of values of ( [symbol] ₁, [symbol] ₂, . . . , [symbol] _{N}) can be found such that the cost function is within a preset limit

The methods described earlier in this disclosure can be used to minimize the respective cost functions of Eqs. 7, 7′, or 7″. If the design variables are characteristics of the projection optics, such as the Zernike coefficients, then minimizing the cost functions of Eqs. 7, 7′, or 7″ leads to process window maximization based on projection optics optimization, i.e., LO. If the design variables are characteristics of the source and patterning device in addition to those of the projection optics, then minimizing the cost function of Eqs. 7, 7′, or 7″ leads to process window maximizing based on SMLO, as illustrated in FIG. 11. If the design variables are characteristics of the source and patterning device and, then minimizing the cost functions of Eqs. 7, 7′, or 7″ leads to process window maximization based on SMO. The cost functions of Eqs. 7, 7′, or 7″ can also include at least one fₚ( [symbol] ₁, [symbol] ₂, . . . , [symbol] _{N}) such as that in Eq. 7 or Eq. 8, that is a function of one or more stochastic effects such as the LWR or local CD variation of 2D features, and throughput.

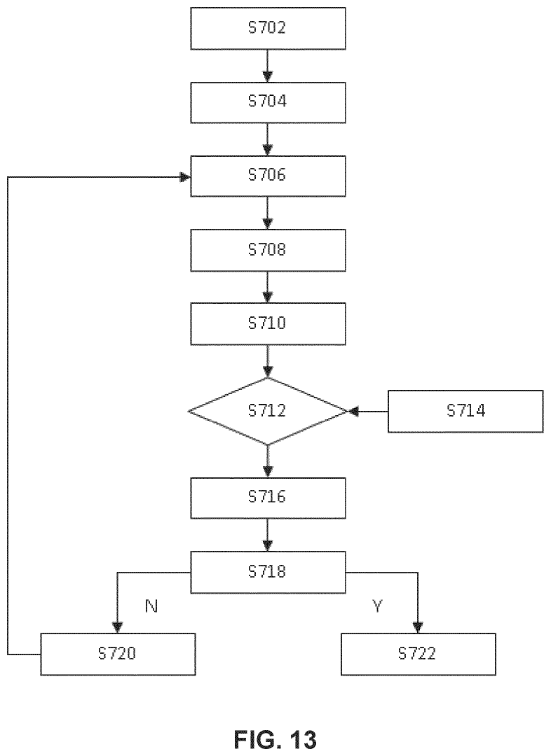

FIG. 13 shows one specific example of how a simultaneous SMLO process can use a Gauss Newton Algorithm for optimization. In step S702, starting values of design variables are identified. Tuning ranges for each variable may also be identified. In step S704, the cost function is defined using the design variables. In step S706 cost function is expanded around the starting values for all evaluation points in the design layout. In optional step S710, a full-chip simulation is executed to cover all critical patterns in a full-chip design layout. Desired lithographic response metric (such as CD or EPE) is obtained in step S714, and compared with predicted values of those quantities in step S712. In step S716, a process window is determined. Steps S718, S720, and S722 are similar to corresponding steps S514, S516 and S518, as described with respect to FIG. 12A. As mentioned before, the final output may be a wavefront aberration map in the pupil plane, optimized to produce the desired imaging performance. The final output may also be an optimized source map and/or an optimized design layout.

FIG. 12B shows an exemplary method to optimize the cost function where the design variables ( [symbol] ₁, [symbol] ₂, . . . , [symbol] _{N}) include design variables that may only assume discrete values.

The method starts by defining the pixel groups of the illumination source and the patterning device tiles of the patterning device (step S802). Generally, a pixel group or a patterning device tile may also be referred to as a division of a lithographic process component. In one exemplary approach, the illumination source is divided into “117” pixel groups, and “94” patterning device tiles are defined for the patterning device, substantially as described above, resulting in a total of “211” divisions.

In step S804, a lithographic model is selected as the basis for photolithographic simulation. Photolithographic simulations produce results that are used in calculations of photolithographic metrics, or responses. A particular photolithographic metric is defined to be the performance metric that is to be optimized (step S806). In step S808, the initial (pre-optimization) conditions for the illumination source and the patterning device are set up. Initial conditions include initial states for the pixel groups of the illumination source and the patterning device tiles of the patterning device such that references may be made to an initial illumination shape and an initial patterning device pattern. Initial conditions may also include mask bias, NA, and focus ramp range. Although steps S802, S804, S806, and S808 are depicted as sequential steps, it will be appreciated that in other embodiments of the invention, these steps may be performed in other sequences.

In step S810, the pixel groups and patterning device tiles are ranked. Pixel groups and patterning device tiles may be interleaved in the ranking Various ways of ranking may be employed, including: sequentially (e.g., from pixel group “1” to pixel group “117” and from patterning device tile “1” to patterning device tile “94”), randomly, according to the physical locations of the pixel groups and patterning device tiles (e.g., ranking pixel groups closer to the center of the illumination source higher), and according to how an alteration of the pixel group or patterning device tile affects the performance metric.

Once the pixel groups and patterning device tiles are ranked, the illumination source and patterning device are adjusted to improve the performance metric (step S812). In step S812, each of the pixel groups and patterning device tiles are analyzed, in order of ranking, to determine whether an alteration of the pixel group or patterning device tile will result in an improved performance metric. If it is determined that the performance metric will be improved, then the pixel group or patterning device tile is accordingly altered, and the resulting improved performance metric and modified illumination shape or modified patterning device pattern form the baseline for comparison for subsequent analyses of lower-ranked pixel groups and patterning device tiles. In other words, alterations that improve the performance metric are retained. As alterations to the states of pixel groups and patterning device tiles are made and retained, the initial illumination shape and initial patterning device pattern changes accordingly, so that a modified illumination shape and a modified patterning device pattern result from the optimization process in step S812.

In other approaches, patterning device polygon shape adjustments and pairwise polling of pixel groups and/or patterning device tiles are also performed within the optimization process of S812.

In an alternative embodiment the interleaved simultaneous optimization procedure may include to alter a pixel group of the illumination source and if an improvement of the performance metric is found, the dose is stepped up and down to look for further improvement. In a further alternative embodiment, the stepping up and down of the dose or intensity may be replaced by a bias change of the patterning device pattern to look for further improvement in the simultaneous optimization procedure.

In step S814, a determination is made as to whether the performance metric has converged. The performance metric may be considered to have converged, for example, if little or no improvement to the performance metric has been witnessed in the last several iterations of steps S810 and S812. If the performance metric has not converged, then the steps of S810 and S812 are repeated in the next iteration, where the modified illumination shape and modified patterning device from the current iteration are used as the initial illumination shape and initial patterning device for the next iteration (step S816).

The optimization methods described above may be used to increase the throughput of the lithographic projection apparatus. For example, the cost function may include an fₚ( [symbol] ₁, [symbol] ₂, . . . , [symbol] _{N}) that is a function of the exposure time. Optimization of such a cost function is preferably constrained or influenced by a measure of the stochastic effects or other metrics. Specifically, a computer-implemented method for increasing a throughput of a lithographic process may include optimizing a cost function that is a function of one or more stochastic effects of the lithographic process and a function of an exposure time of the substrate, in order to minimize the exposure time.

In one embodiment, the cost function includes at least one fₚ( [symbol] ₁, [symbol] ₂, . . . , [symbol] _{N}) that is a function of one or more stochastic effects. The stochastic effects may include the failure of a feature, measurement data (e.g., SEPE) determined as in method of FIG. 3, LWR or local CD variation of 2D features. In one embodiment, the stochastic effects include stochastic variations of characteristics of a resist image. For example, such stochastic variations may include failure rate of a feature, line edge roughness (LER), line width roughness (LWR) and critical dimension uniformity (CDU). Including stochastic variations in the cost function allows finding values of design variables that minimize the stochastic variations, thereby reducing risk of defects due to stochastic effects.

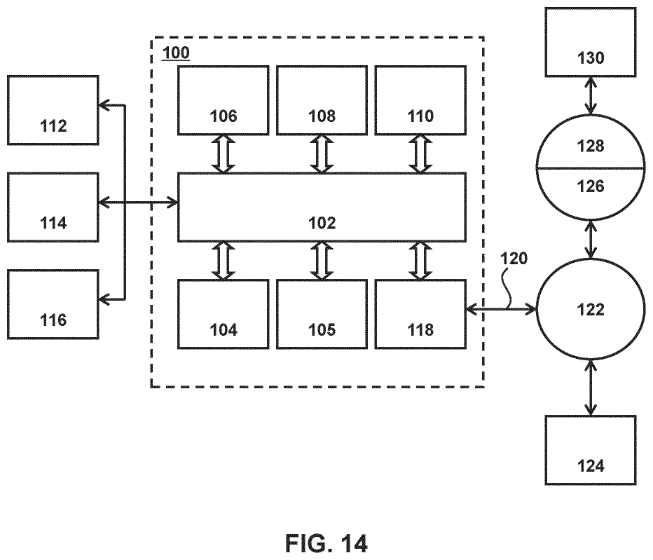

FIG. 14 is a block diagram that illustrates a computer system 100 which can assist in implementing the systems and methods disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also preferably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

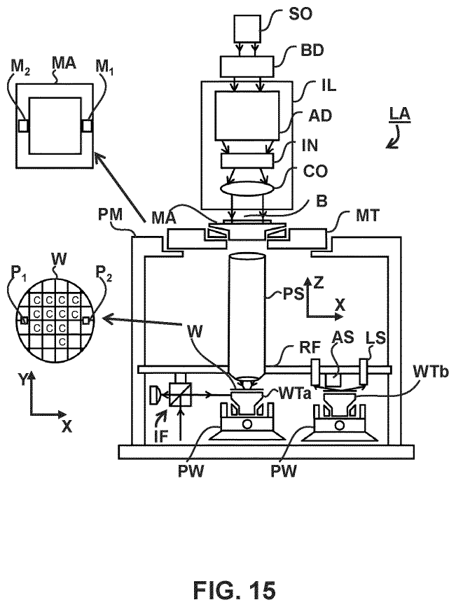

FIG. 15 schematically depicts an exemplary lithographic projection apparatus whose illumination source could be optimized utilizing the methods described herein. The apparatus comprises:
an illumination system IL, to condition a beam B of radiation. In this particular case, the illumination system also comprises a radiation source SO;
a first object table (e.g., mask table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive mask). However, in general, it may also be of a reflective type, for example (with a reflective mask). Alternatively, the apparatus may employ another kind of patterning device as an alternative to the use of a classic mask; examples include a programmable mirror array or LCD matrix.

The source SO (e.g., a mercury lamp or excimer laser) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 15 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g., so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 15. However, in the case of a wafer stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

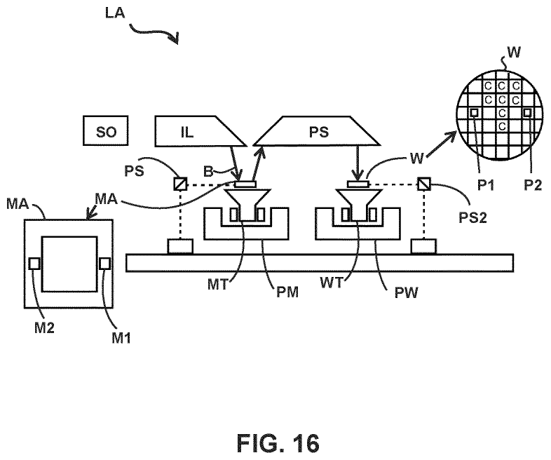

35 FIG. 16 schematically depicts another exemplary lithographic projection apparatus LA whose illumination source could be optimized utilizing the methods described herein.

The lithographic projection apparatus LA includes:
a source collector module SO
an illumination system (illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

As here depicted, the apparatus LA is of a reflective type (e.g., employing a reflective mask). It is to be noted that because most materials are absorptive within the EUV wavelength range, the mask may have multilayer reflectors comprising, for example, a multi-stack of Molybdenum and Silicon. In one example, the multi-stack reflector has a 40-layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 16, the illuminator IL receives an extreme ultraviolet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 16, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks Ml, M2 and substrate alignment marks P1, P2.

The depicted apparatus LA could be used in at least one of the following modes:

1. In step mode, the support structure (e.g., mask table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-)magnification and image reversal characteristics of the projection system PS.

3. In another mode, the support structure (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

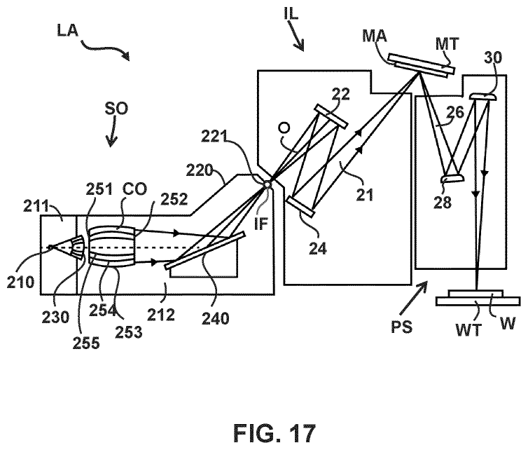

FIG. 17 shows the apparatus LA in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contaminant trap 230 may also include a gas barrier or a combination of a gas barrier and a channel structure. The contaminant trap or contaminant trap 230 further indicated herein at least includes a channel structure, as known in the art.

The collector chamber 212 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the radiation beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 17.

Collector optic CO, as illustrated in FIG. 17, is depicted as a nested collector with grazing incidence reflectors 253, 254 and 255, just as an example of a collector (or collector mirror).

The grazing incidence reflectors 253, 254 and 255 are disposed axially symmetric around the optical axis O and a collector optic CO of this type is preferably used in combination with a discharge produced plasma source, often called a DPP source.

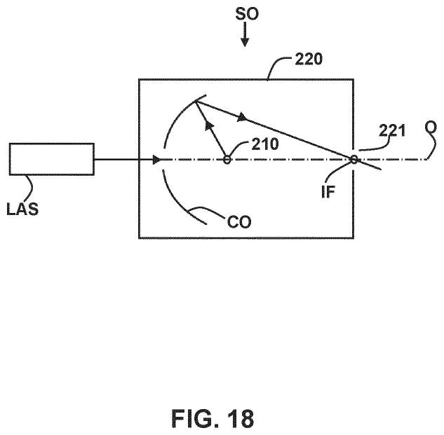

Alternatively, the source collector module SO may be part of an LPP radiation system as shown in FIG. 18. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a

patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

Embodiments of the present disclosure can be further described by the following clauses.

1. A non-transitory computer-readable medium having instructions that, when executed by a computer, cause the computer to execute a method for training a machine learning model using a composite image of a target pattern and reference layer patterns to predict a post-optical proximity correction (OPC) image, wherein the post-OPC image is used to obtain a post-OPC mask for printing a target pattern on a substrate, the method comprising:
obtaining (a) target pattern data representative of a target pattern to be printed on a substrate and (b) reference layer data representative of a reference layer pattern associated with the target pattern;
rendering a target image from the target pattern data and a reference layer pattern image from the reference layer pattern;
generating a composite image by combining the target image and the reference layer pattern image; and
training a machine learning model with the composite image to predict a post-OPC image until a difference between the predicted post-OPC image and a reference post-OPC image corresponding to the composite image is minimized
   2. A non-transitory computer-readable medium having instructions that, when executed by a computer, cause the computer to execute a method for generating a post-optical proximity correction (OPC) image, wherein the post-OPC image is used in generating a post-OPC mask pattern to print a target pattern on a substrate, the method comprising:
providing an input that is representative of images of (a) a target pattern to be printed on a substrate and (b) a reference layer pattern associated with the target pattern to a machine learning model; and
generating, using the machine learning model, a post-OPC result based on the images.
   3. The computer-readable medium of clause 2, wherein providing the input includes:
rendering a first image based on the target pattern;
rendering a second image based on the reference layer pattern; and
providing the first image and the second image to the machine learning model.
   4. The computer-readable medium of clause 2, wherein providing the input includes: providing a composite image that is a combination of a first image corresponding to the target pattern and a second image corresponding to the reference layer pattern.
   5. The computer-readable medium of clause 4, wherein providing the composite image includes:
rendering the first image based on the target pattern;
rendering the second image based on the reference layer pattern, and
combining the first image and the second image to generate the composite image.

6. The computer-readable medium of clause 4, wherein combining the first image with the second image includes combing the first image, the second image, a third image corresponding to sub-resolution assist features (SRAF) and a fourth image corresponding to sub-resolution inverse features (SRIF) to generate the composite image

7. The computer-readable medium of clause 4, wherein the first image and the second image are combined using a linear function to generate the composite image.
8. The computer-readable medium of clause 2, wherein the post-OPC result includes:
a rendered post-OPC image of a mask pattern, wherein the mask pattern corresponds to the target pattern to be printed on the substrate.
   9. The computer-readable medium of clause 2, wherein the post-OPC image includes:
a reconstructed image of a mask pattern, wherein the mask pattern corresponds to the target pattern to be printed on the substrate.
   10. The computer-readable medium of clause 2, wherein the reference layer pattern is a pattern of design layer or a derived layer different from the target pattern, wherein the reference layer pattern impacts an accuracy of correction of the target pattern in an OPC process.
   11. The computer-readable medium of clause 2, wherein the reference layer pattern includes a context layer pattern or a dummy pattern.
   12. The computer readable medium of clause 2 further comprising:
performing a patterning step using the post-OPC result to print patterns corresponding to the target pattern on the substrate via a lithographic process.
   13. The computer-readable medium of clause 2, wherein generating the post-OPC result includes training the machine learning model to generate the post-OPC result based on the input.
   14. The computer-readable medium of clause 13, wherein training the machine learning model includes:
obtaining input related to (a) a first target pattern to be printed on a first substrate, (b) a first reference layer pattern associated with the first target pattern, and (c) a first reference post-OPC result corresponding to the first target pattern, and
training the machine learning model using the first target pattern and the first reference layer pattern such that a difference between the first reference post-OPC result and a predicted post-OPC result of the machine learning model is reduced.
   15. The computer-readable medium of clause 14, wherein the training is an iterative process, an iteration comprises:
providing the input to the machine learning model,
generating the predicted post-OPC result using the machine learning model,
computing a cost function that is indicative of a difference between the predicted post-OPC result and the first reference post-OPC result, and
adjusting parameters of the machine learning model such that the difference between the predicted post-OPC result and the first reference post-OPC result is reduced.
   16. The computer-readable medium of clause 15, wherein the difference is minimized
   17. The computer-readable medium of clause 16, wherein the obtaining of the first reference post-OPC result includes:
performing a mask optimization process or a source mask optimization process using the first target pattern to generate the first reference post-OPC result.
   18. The computer-readable medium of clause 17, wherein the first reference post-OPC result is a reconstructed image of a mask pattern corresponding to the first target pattern.
   19. The computer-readable medium of clause 18, wherein the mask pattern is modified prior to the reconstructed image is generated.
   20. The computer-readable medium of clause 14, wherein the input includes an image of the first target pattern and an image of the first reference layer pattern.
   21. The computer-readable medium of clause 14, wherein the input includes a composite image, wherein the composite image is a combination of an image corresponding to the first target pattern and an image corresponding to the first reference layer pattern.
   22. A non-transitory computer-readable medium having instructions that, when executed by a computer, cause the computer to execute a method for generating a post-optical proximity correction (OPC) image, wherein the post-OPC image is used to generate a post-OPC mask to print a target pattern on a substrate, the method comprising:
providing a first image representing a target pattern to be printed on a substrate and a second image representing a reference layer pattern associated with the target pattern to a machine learning model; and
generating, using the machine learning model, a post-OPC image based on the target pattern and the reference layer pattern.
   23. The computer-readable medium of clause 22 further comprising:
generating a post-OPC mask using the post-OPC image, the post-OPC mask used to print the target pattern on a substrate.
   24. The computer-readable medium of clause 22, wherein the post-OPC image is an image of a mask pattern or a reconstructed image of the mask pattern, wherein the mask pattern corresponds to the target pattern to be printed on the substrate.
   25. A non-transitory computer-readable medium having instructions that, when executed by a computer, cause the computer to execute a method for generating a post-optical proximity correction (OPC) image, wherein the post-OPC image is used to generate a post-OPC mask to print a target pattern on a substrate, the method comprising:
providing a composite image representing (a) a target pattern to be printed on a substrate and
   (b) a reference layer pattern associated with the target pattern to a machine learning model; and
generating, using the machine learning model, a post-OPC image based on the target pattern and the reference layer pattern.
   26. The computer-readable medium of clause 25 further comprising:
generating a post-OPC mask using the post-OPC image, the post-OPC mask used to print the target pattern on a substrate.
   27. The computer-readable medium of clause 25, wherein the composite image is a combination of a first image corresponding to the target pattern and a second image corresponding to the reference layer pattern.
   28. The computer-readable medium of clause 25, wherein providing the composite image includes:
rendering the first image based on the target pattern,
rendering the second image based on the reference layer pattern, and
combining the first image and the second image to generate the composite image.
   29. The computer-readable medium of clause 25, wherein the first image and the second image are combined using a linear function to generate the composite image.
   30. A non-transitory computer-readable medium having instructions that, when executed by a computer, cause the computer to execute a method for training a machine learning model to generate a post-optical proximity correction (OPC) image, the method comprising:
obtaining input related to (a) a first target pattern to be printed on a first substrate, (b) a first reference layer pattern associated with the first target pattern, and (c) a first reference post-OPC image corresponding to the first target pattern; and
training the machine learning model using the first target pattern and the first reference layer pattern such that a difference between the first reference post-OPC image and a predicted post-OPC image of the machine learning model is reduced.
   31. The computer-readable medium of clause 30, wherein the training is an iterative process, an iteration comprises:
providing the input to the machine learning model,
generating the predicted post-OPC image using the machine learning model,
computing a cost function that is indicative of a difference between the predicted post-OPC image and the first reference post-OPC image, and
adjusting parameters of the machine learning model such that the difference between the predicted and reference images is reduced.
   32. The computer-readable medium of clause 31, wherein the difference is minimized
   33. The computer-readable medium of clause 30, wherein obtaining the first reference post-OPC result includes:
performing a mask optimization process or a source mask optimization process using the first target pattern to generate the first reference post-OPC result.
   34. The computer-readable medium of clause 30, wherein the first post-OPC result includes an image of a mask pattern or a reconstructed image of the mask pattern, wherein the mask pattern corresponds to the first target pattern.
   35. A method for generating a post-optical proximity correction (OPC) image, wherein the post-OPC image is used in generating a post-OPC mask pattern to print a target pattern on a substrate, the method comprising:
providing an input that is representative of images of (a) a target pattern to be printed on a substrate and (b) a reference layer pattern associated with the target pattern to a machine learning model; and
generating, using the machine learning model, a post-OPC result based on the images.
   36. A method for generating a post-optical proximity correction (OPC) image, wherein the post-OPC image is used to generate a post-OPC mask to print a target pattern on a substrate, the method comprising:
providing a first image representing a target pattern to be printed on a substrate and a second image representing a reference layer pattern associated with the target pattern to a machine learning model; and
generating, using the machine learning model, a post-OPC image based on the target pattern and the reference layer pattern.
   37. A method for generating a post-optical proximity correction (OPC) image, wherein the post-OPC image is used to generate a post-OPC mask to print a target pattern on a substrate, the method comprising:
providing a composite image representing (a) a target pattern to be printed on a substrate and (b) a reference layer pattern associated with the target pattern to a machine learning model; and
generating, using the machine learning model, a post-OPC image based on the target pattern and the reference layer pattern.
   38. A method for training a machine learning model to generate a post-optical proximity correction (OPC) image, the method comprising:
obtaining input related to (a) a first target pattern to be printed on a first substrate, (b) a first reference layer pattern associated with the first target pattern, and (c) a first reference post-OPC image corresponding to the first target pattern; and
training the machine learning model using the first target pattern and the first reference layer pattern such that a difference between the first reference post-OPC image and a predicted post-OPC image of the machine learning model is reduced.
   39. An apparatus for generating a post-optical proximity correction (OPC) image, wherein the post-OPC image is used in generating a post-OPC mask pattern to print a target pattern on a substrate, the apparatus comprising:
a memory storing a set of instructions; and
a processor configured to execute the set of instructions to cause the apparatus to perform a method of:
   providing an input that is representative of images of (a) a target pattern to be printed on a substrate and (b) a reference layer pattern associated with the target pattern to a machine learning model; and
   generating, using the machine learning model, a post-OPC result based on the images

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A non-transitory computer-readable medium having instructions that, when executed by a computer system, are configured to cause the computer system to at least:
provide an input that is representative of images of (a) a target pattern to be printed on a substrate and (b) a reference layer pattern associated with the target pattern, to a machine learning model; and
generate, using the machine learning model, a post-optical proximity correction (OPC) result based on the images, wherein the post-OPC result is for use in generating a post-OPC mask pattern to print the target pattern.

2. The computer-readable medium of claim 1, wherein the instructions configured to cause the computer system to provide the input are further configured to cause the computer system to:
render a first image based on the target pattern;
render a second image based on the reference layer pattern; and
provide the first image and the second image to the machine learning model.

3. The computer-readable medium of claim 2, wherein the instructions configured to cause the computer system to provide the input are further configured to cause the computer system to provide a composite image that is a combination of a first image corresponding to the target pattern and a second image corresponding to the reference layer pattern.

4. The computer-readable medium of claim 3, wherein the instructions configured to cause the computer system to provide the composite image are further configured to cause the computer system to:
render the first image based on the target pattern;
render the second image based on the reference layer pattern, and
combine the first image and the second image to generate the composite image.

5. The computer-readable medium of claim 3, wherein the combination of the first image and the second image further includes combination with the first image and the second image, of a third image corresponding to sub-resolution assist features (SRAF) and a fourth image corresponding to sub-resolution inverse features (SRIF) to generate the composite image.

6. The computer-readable medium of claim 3, wherein the first image and the second image are combined using a linear function to generate the composite image.

7. The computer-readable medium of claim 1, wherein the post-OPC result includes a rendered post-OPC image of a mask pattern, wherein the mask pattern corresponds to the target pattern to be printed on the substrate.

8. The computer-readable medium of claim 1, wherein the post-OPC image includes a reconstructed image of a mask pattern, wherein the mask pattern corresponds to the target pattern to be printed on the substrate.

9. The computer-readable medium of claim 1, wherein the reference layer pattern is a pattern of a design layer or a derived layer different from the target pattern, wherein the reference layer pattern impacts an accuracy of correction of the target pattern in an OPC process.

10. The computer-readable medium of claim 1, wherein the reference layer pattern includes a context layer pattern or a dummy pattern.

11. The computer-readable medium of claim 1, wherein the instructions are further configured to cause the computer system to train the machine learning model to generate the post-OPC result based on the input.

12. The computer-readable medium of claim 11, wherein the instructions configured to cause the computer system to train the machine learning model are further configured to cause the computer system to:
obtain input related to (a) a first target pattern to be printed on a first substrate, (b) a first reference layer pattern associated with the first target pattern, and (c) a first reference post-OPC result corresponding to the first target pattern, and
train the machine learning model using the first target pattern and the first reference layer pattern such that a difference between the first reference post-OPC result and a predicted post-OPC result of the machine learning model is reduced.

13. The computer-readable medium of claim 12, wherein the instructions configured to cause the computer system to obtain the first reference post-OPC result are further configured to cause the computer system to perform a mask optimization process or a source mask optimization process using the first target pattern to generate the first reference post-OPC result.

14. The computer-readable medium of claim 13, wherein the first reference post-OPC result is a reconstructed image of a mask pattern corresponding to the first target pattern.

15. The computer-readable medium of claim 14, wherein the mask pattern is modified prior to the reconstructed image is generated.

16. A non-transitory computer-readable medium having instructions that, when executed by a computer system, cause the computer system to at least:
obtain (a) target pattern data representative of a target pattern to be printed on a substrate and (b) reference layer data representative of a reference layer pattern associated with the target pattern;
render a target image from the target pattern data and a reference layer pattern image from the reference layer pattern;
generate a composite image by combining the target image and the reference layer pattern image; and
train a machine learning model with the composite image to predict a post-optical proximity correction (OPC) image until a difference between the predicted post-OPC image and a reference post-OPC image corresponding to the composite image is minimized, wherein the post-OPC image is for use in obtaining a post-OPC mask for printing a target pattern on a substrate.

17. A non-transitory computer-readable medium having instructions that, when executed by a computer system, are configured to cause the computer system to at least:
obtain input related to (a) a first target pattern to be printed on a first substrate, (b) a first reference layer pattern associated with the first target pattern, and (c) a first reference post-optical proximity correction (OPC) image corresponding to the first target pattern; and
train a machine learning model using the first target pattern and the first reference layer pattern such that a difference between the first reference post-OPC image and a predicted post-OPC image of the machine learning model is reduced.

18. The computer-readable medium of claim 17, wherein the instructions configured to cause the computer system to train the machine learning model are further configured to cause the computer system to:
provide the input to the machine learning model,
generate the predicted post-OPC image using the machine learning model,
compute a cost function that is indicative of a difference between the predicted post-OPC image and the first reference post-OPC image, and
adjust one or more parameters of the machine learning model such that the difference between the predicted post-OPC image and the first reference post-OPC image is reduced.

19. The computer-readable medium of claim 17, wherein the instructions configured to cause the computer system to obtain the first reference post-OPC image are further configured to cause the computer system to perform a mask optimization process or a source mask optimization process using the first target pattern to generate the first reference post-OPC image.

20. The computer-readable medium of claim 17, wherein the first reference post-OPC image includes an image of a mask pattern or a reconstructed image of the mask pattern, wherein the mask pattern corresponds to the first target pattern.
